(19) United States
(12) Patent Application Publication
(10) Pub. No.: US 2009/0267489 A1
(43) Pub. Date: Oct. 29, 2009

(54) GAS BARRIER THIN FILM LAMINATE, GAS BARRIER RESIN SUBSTRATE AND ORGANIC EL DEVICE

(75) Inventors: Hiroaki Arita, Tokyo (JP); Kazuhiro Fukuda, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA HOLDINGS, INC., Tokyo (JP)

(21) Appl. No.: 11/721,855

(22) PCT Filed: Dec. 6, 2005
(86) PCT No.: PCT/JP2005/022323

§ 371 Date: Jun. 15, 2007

(30) Foreign Application Priority Data
Dec. 20, 2004 (JP) 2004-367420
Mar. 17, 2005 (JP) 2005-077337

(51) Int. Cl. H01L 51/50; B32B 15/00

(52) U.S. Cl. 313/504; 428/688; 428/702; 428/698

(57) ABSTRACT

Disclosed is a gas-barrier thin film laminate which can be produced with high yield while having higher gas barrier properties than the conventional ones. The gas barrier properties of this gas-barrier thin film laminate do not deteriorate even when the laminate is bent. Also disclosed is an organic EL device (hereinafter also referred to as OLED) with excellent environmental resistance which uses the gas-barrier thin film laminate. The gas-barrier thin film laminate having at least one inorganic film and at least one stress relaxation film is characterized in that at least one stress relaxation film is formed by an atmospheric pressure plasma method wherein two or more electric fields of different frequencies are applied.

### FIELD OF THE INVENTION

The present invention relates to a gas barrier thin film laminate, a gas barrier resin substrate containing a gas barrier thin film laminate, and an organic EL device which is sealed by using a gas barrier thin film laminate or a gas barrier resin substrate.

### BACKGROUND OF THE INVENTION

In the conventional art, the gas barrier film having a thin film of a metallic oxide such as aluminum oxide, magnesium oxide and silicon oxide formed on the plastic substrate or a film surface has been used over an extensive range for packaging articles which require blocking of various types of gasses such as moisture and oxygen, or for packaging to prevent degeneration of the food, industrial products and pharmaceuticals. Apart from packaging, this film has also been employed, for example, in a liquid crystal display device, solar cell and electroluminescence (EL) substrate. Specifically, the transparent substrate which is currently placed in the advanced phase of application in the field of a liquid crystal display device and EL device is requested to meet the requirements of more sophisticated nature such as long-term reliability, a high degree of freedom in shape and capacity of displaying on a curved surface, in addition to the requirements for reduced weight and increased size, in recent years. Instead of a glass substrate characterized by heaviness, vulnerability and difficulty in increasing the size, a film substrate such as a transparent plastic is coming into widespread use.

Further, in addition to meeting the aforementioned requirements, the plastic film can be used in the roll-to-roll method, and is characterized by superb productivity as compared to a glass substrate. Thus, the plastic film offers cost cutting advantages as well.

However, such a film substrate as a transparent plastic substrate is inferior to glass with regard to gas barrier function. Use of a substrate having an inferior gas barrier function allows permeation of moisture or air. For example, it deteriorates the electrode inside a liquid crystal cell to cause display failure, whereby display quality is deteriorated.

One of the known methods to solve the aforementioned problems is to provide a gas barrier film substrate by forming a metallic oxide thin film on a film substrate. The gas barrier film with silicon oxide vapor-deposited on a plastic film (Patent Document 1) and the gas barrier film with aluminum oxide vapor-deposited on a plastic film (Patent Document 2) have been known as the gas barrier film used as a packaging material or in a liquid crystal display device. They have a moisture barrier property of about 1 g/m²/day.

In recent years, gas barrier property of a film substrate is required to reach a high level of up to about 0.1 g/m²/day in terms of a moisture shielding effect, due to the development of a large screen organic EL display or a high resolution display, which require a further improved gas barrier function.

To meet the aforementioned requirements and to find out a method that can be expected to provide higher barrier performances, a study is being made to develop a film formation technique based on the sputtering method and CVD method for forming a thin film by using plasma generated by glow discharge under low pressure conditions. Further, another attempt of such a study is shown by a technique of manufacturing a barrier film having a stress relaxation film/inorganic film alternating lamination structure according to the vacuum vapor-deposition method (Patent Document 3).

However, these thin film forming methods require processing to be carried out under a low pressure condition. To obtain a low pressure, a high-priced vacuum chamber must be used as a container. Further, a vacuum evacuation apparatus must be installed. If an attempt is made to form a large-area substrate for processing under vacuum, a large vacuum container must be used, and a vacuum evacuation apparatus of high power is required. As a result, the equipment cost is increased. Also, when a surface treatment of a plastic substrate having a high percentage of water absorption is conducted, due to the vaporization of absorbed moisture, a long time is required to obtain a desired degree of vacuum, resulting in increase of processing costs. In addition to these disadvantages, the vacuum of the vacuum container must be broken for each step of processing to take out the contents, in order to carry out a succeeding processes such as the process of forming a stress relaxation film which must be carried out under atmospheric pressure. The more the number of the stress relaxation film and the inorganic film is increased, in order to obtain a higher moisture barrier performance, the lower the productivity becomes.

Regarding a barrier film containing a stress relaxation film/inorganic film alternating lamination structure, in the meantime, a method of forming an inorganic film by discharge plasma processing in the vicinity of atmospheric pressure has been disclosed. Further, stress relaxation film forming method is mentioned as a coating and vacuum film forming method (Patent Document 4). In this method, however, although an inorganic film is formed according to the atmospheric pressure plasma method, productivity will be reduced if the stress relaxation film is formed by the coating method requiring a drying process or the vacuum film forming method requiring a vacuum chamber. In the inorganic film forming method having been disclosed, high-priced argon as an electrical discharge gas must be used, and this results in a cost increase. The processing condition based on the commonly known single-frequency pulse electric field as disclosed in the Patent Document 5, for example, is used as a discharge plasma processing condition. Thus, the plasma density is low and high-quality film cannot be obtained. Moreover, the film making speed is low, and hence productivity is very low.

Patent Document 1: Examined Japanese Patent Publication No. 53-12953

Patent Document 2: Japanese Patent Application Publication (hereafter referred to as JP-A) No. 58-217344

Patent Document 3: International Publication No. 00/026973

Patent Document 4: JP-A No. 2003-191370

Patent Document 5: JP-A No. 2001-49443

### DISCLOSURE OF THE INVENTION

### Problems to be Solved by the Invention

The present invention has been made in the foregoing circumstances. An object of the present invention is to provide a gas barrier thin film laminate characterized by a higher gas barrier performance without deterioration of barrier performance even by bending, and an organic EL device (hereinafter, also referred to as “OLED”) characterized by environmental resistance ensured by this gas barrier thin film laminate, wherein the gas barrier thin film laminate is provided through enhanced productivity.

### Method to Solve the Problem

The above object of the present invention is achieved by the following structures.

1. A gas barrier thin film laminate comprising an inorganic film and a stress relaxation film, wherein the stress relaxation film is formed by an atmospheric pressure plasma method, wherein two or more electric fields having different frequencies are applied in the atmospheric pressure plasma method.
2. The gas barrier thin film laminate of Item 1, wherein the stress relaxation film is produced by the atmospheric pressure plasma method by introducing a thin film forming gas into a plasma space, the thin film forming gas comprising an organic compound having an unsaturated bond or a ring structure.
3. The gas barrier thin film laminate of Item 1, wherein the stress relaxation film is produced by the atmospheric pressure plasma method by introducing a thin film forming gas into a plasma space, the thin film forming gas comprising:

an organic compound having an unsaturated bond or a ring structure; and

an organometallic compound.

4. The gas barrier thin film laminate of Item 2 or 3, wherein the organic compound having an unsaturated bond or a ring structure is at lest one selected from the group consisting of a (meth)acryl compound, an epoxy compound and an oxetane compound.
5. The gas barrier thin film laminate of any one of Items 1 to 4, wherein the thin film forming gas comprises nitrogen gas as a main component, the thin film forming gas being introduced into the plasma space in the atmospheric pressure plasma method.
6. The gas barrier thin film laminate of any one of Items 2 to 5, wherein the thin film forming gas comprises, as an additive gas, at least one organic compound selected from the group consisting of a group of hydrocarbons, a group of alcohols and a group of organic acids.
7. The gas barrier thin film laminate of any one of Items 1 to 6, wherein the inorganic film comprises at least one selected from the group consisting of a metal oxide, a metal nitride-oxide and a metal nitride, as a main component.
8. The gas barrier thin film laminate of any one of Items 1 to 7, wherein the inorganic film is formed by an atmospheric pressure plasma method by applying two or more electric fields having different frequencies.
9. The gas barrier thin film laminate of any one of Items 1 to 8, wherein an adhesive layer is provided between the stress relaxation film and the inorganic film.
10. The gas barrier thin film laminate of Item 9, wherein the adhesive layer is at least one selected from the group consisting of a metal oxide, a metal nitride-oxide and a metal nitride each containing 1 to 50% carbon.
11. A gas barrier resin substrate comprising a resin substrate having the gas barrier thin film laminate of any one of Items 1 to 10 on one surface of the resin substrate.
12. The gas barrier resin substrate of Item 11, wherein the resin substrate has a glass transition temperature of 150° C. or more.
13. An organic EL device comprising:

a substrate having thereon electrodes and an organic compound layer; and

a sealing film provided to cover the electrodes and the organic compound layer,

wherein the sealing film is the gas barrier thin film laminate of any one of Items 1 to 10.

14. An organic EL device comprising:

a substrate having thereon electrodes and an organic compound layer; and

a sealing film provided to cover the electrodes and the organic compound layer, the sealing film being adhered with the substrate to seal the electrodes and the organic compound layer,

wherein the sealing film is the gas barrier resin substrate of Item 11 or 12.

15. The organic EL device of Item 13 or 14, wherein the substrate having thereon the electrodes and the organic compound layer is the gas barrier resin substrate of Item 11 or 12.

### EFFECT OF THE INVENTION

The present invention provides a gas barrier thin film laminate characterized by a high gas barrier performance, without the moisture barrier performance being deteriorated by bending. Moreover, the productivity of the gas barrier thin film laminate is from several times to several tens of times more than that of the conventional product. If the gas barrier thin film laminate or gas barrier resin substrate of the present invention is applied to a display element, for example, it is possible to manufacture a display characterized by reduced weight and cost, without possibility of being cracked. Thus, the industrial value of the present invention is extremely high.

### BRIEF DESCRIPTION OF THE DRAWINGS

FIG. 1 is a schematic view showing an example of a jet type atmospheric pressure plasma discharge processing apparatus preferably used in the present invention.

FIG. 2 is a schematic view showing an example of the atmospheric pressure plasma discharge processing apparatus for processing a substrate between opposing electrodes preferably used in the present invention.

FIG. 3 is a perspective view representing an example of the structure of the conductive metallic base material of a roll rotating electrode and the dielectric covering the same.

FIG. 4 is a perspective view representing an example of the structure of the conductive metallic base material of a rectangular electrode and the dielectric covering the same.

FIG. 5 is a cross sectional view showing an example of the structure of the gas barrier resin substrate of the present invention.

FIG. 6 is a cross sectional view showing an example of the sealed form of an organic EL device.

FIG. 7 is a cross sectional view showing another example of the sealed form of an organic EL device.

FIG. 8 is a cross sectional view showing an example of the organic EL device formed on the gas barrier resin substrate of the present invention and sealed by the gas barrier thin film laminate of the present invention.

FIG. 9 is a cross sectional view showing an example of the organic EL device formed on the gas barrier resin substrate of the present invention and sealed by the gas barrier resin substrate of the present invention.

FIG. 10 is a cross sectional view showing an example of the organic EL device formed on the gas barrier resin substrate of the present invention and sealed by a glass-made can member.

FIG. 11 is a diagram showing an example of the pulse electric field applied to the electrode.

### DESCRIPTION OF REFERENCE NUMERALS

1 Resin substrate
2 Glass substrate
3 Gas barrier function laminate
4 Anode
5 Organic compound layer
6 Cathode
8 Can member
9 Adhesive
10 Plasma discharge processing apparatus
11 First electrode
12 Second electrode
21 First power source
30 Plasma discharge processing apparatus
32 Discharge space
35 Roll rotating electrode
35a Roll electrode
35A Metallic base material
35B Dielectric
36 Rectangular fixed electrode group
40 Electric field application section
41 First power source
42 Second power source
50 Gas supply section
51 Gas generating apparatus
52 Gas inlet
53 Exhaust outlet
60 Electrode temperature adjusting section
G Thin film forming gas
G° Plasmic gas
G″ Processed exhaust gas

### DESCRIPTION OF THE PREFERRED EMBODIMENTS

The following describes the best mode of the embodiment of the present invention, however, the present invention is not limited thereto.

The present inventors have made efforts to achieve the aforementioned object and have found out that, in a gas barrier thin film laminate containing at least one layer of each of the stress relaxation films and inorganic films, at least one layer of the aforementioned stress relaxation films is formed as the atmospheric pressure plasma polymerized film which is produced by the atmospheric pressure plasma method wherein two or more electric fields having different frequencies are applied, at least one type of organic compound being contained in a thin film forming gas, whereby an excellent gas barrier performance and superb resistance to bending can be achieved and a superb OLED resistance to environment can be provided by application of this arrangement to an organic EL device (OLED).

In the first place, the following describes the stress relaxation film of the present invention:

<<Stress Relaxation Film>>

The stress relaxation film of the present invention can be defined as a film that protects an “inorganic film having the effect of shutting off such gases as a moisture and oxygen” against bending and other stresses that may occur. Thus, the gas barrier thin film laminate of the present invention is made up of a lamination of the inorganic film equipped with the effect of shutting off such gases as a moisture and oxygen, and the stress relaxation film.

The stress relaxation film of the present invention is formed by the atmospheric pressure plasma method wherein two or more electric fields having different frequencies are applied. This stress relaxation film formed by the atmospheric pressure plasma method is a plasma polymerized film formed by the process wherein the thin film forming gas containing at least one type of the organic compounds having at least one unsaturated bondage or ring structure is introduced into the plasma space.

The thickness of the stress relaxation film of the present invention is approximately in the range from 5 through 500 nm. This film forms a less hard layer for protecting the inorganic film of the present invention against bending or other stresses that may occur.

The stress relaxation film made up of such a structure is more flexible than the inorganic film. Thus, when it is laminated with an inorganic film to form a gas barrier thin film laminate, the resistance to bending is enhanced and the bondability between layers is upgraded by the improved flexibility of the overall formed layer.

The stress relaxation film of the present invention is formed by the atmospheric pressure plasma method, and the atmospheric pressure plasma method wherein two or more electric fields having different frequencies are applied.

The following describes the details of the atmospheric pressure plasma method wherein two or more electric fields having different frequencies of the present invention are applied:

In the first place, the following describes the thin film forming gas used to form a stress relaxation film of the present invention:

The thin film forming gas is used as a material gas in the atmospheric pressure plasma method and is made up of an electrical discharge gas and material component. An additive gas can also be used.

Commonly known organic compounds can be utilized as the organic compound as one of the material components of the stress relaxation film of the present invention. Of these compounds, the organic compound containing at least one unsaturated bond or cyclic structure in the molecule is preferably used. The monomer or oligomer of (meth)acryl compound, epoxy compound or oxetane compound is preferably employed in particular.

In the present invention, the organic compound containing an unsaturated bondage is exemplified by:

vinyl esters such as vinyl acetate, vinyl propionate, vinyl butyrate, vinyl isobutyrate, vinyl valerate, vinyl pivalate, vinyl caproate, vinyl enanthate, vinyl caprylate, vinyl caprate, vinyl laurate, vinyl myristate, vinyl palmitate, vinyl stearate, vinyl cyclohexane carboxylate, vinyl sorbate, and vinyl benzoate;

vinyl ethers such as methyl vinyl ether, ethyl vinyl ether, propyl vinyl ether, butyl vinyl ether, 2-ethylhexylvinyl ether, and hexylvinyl ether;

styrenes such as styrene, 4-[(2-butoxyethoxy) methyl]styrene, 4-butoxymethoxystyrene, 4-butylstyrene, 4-desylstyrene, 4-(2-ethoxymethyl) styrene, 4-(1-ethylhexyloxymethyl) styrene, 4-hydroxymethyl styrene, 4-hexyl styrene, 4-nonyl styrene, 4-octyl oxymethyl styrene, 2-octyl styrene, 4-octyl styrene and 4-propoxymethyl styrene; and

Maleic acids such as dimethyl maleic acid, diethyl maleic acid, dipropyl maleic acid, dibutyl maleic acid, dicyclohexyl maleic acid, di-2-ethylhexyl maleic acid, dinonyl maleic acid, dibenzyl maleic acid,

wherein the aforementioned organic compound is not restricted to these examples.

There is no restriction on particular (meth)acryl compound to be used in the present invention. Examples are:

monofunctional acrylic acid esters such as 2-ethylhexylacrylate, 2-hydroxy propyl acrylate, glycerol acrylate, tetrahydrofurfuryl acrylate, phenoxy ethylacrylate, nonylphenoxy ethylacrylate, tetrahydrofurfuryl oxyethylacrylate, tetrahydrofurfuryloxy hexanolide acrylate, acrylate of s-caprolactone adduct of 1,3-dioxane alcohol and 1,3-dioxolaneacrylate; or

methacrylic acid ester wherein acrylate is replaced by methacrylate as exemplified by:

bifunctional acrylic acid esters such as ethylene glycolate diacrylate, triethylene glycol diacrylate, pentaerythritol diacrylate, hydroquinone diacrylate, resorcin diacrylate, hexanediol diacrylate, neopentyl glycolate diacrylate, tripropylene glycolate diacrylate, diacrylate of neopentylglycolate hydroxypivalate, diacrylate of neopentyl glycoladipate, diacrylate of ∈-caprolactone adduct of neopentyl glycolate hydroxypivalate, 2-(2-hydroxy-1,1-dimethylethyl)-5-hydroxymethyl-5-ethyl-1,3-dioxane diacrylate, tricyclodecane di methylol acrylate, ∈-caprolactone adduct of tricyclodecane di methylol acrylate, and diacrylate of diglycidyl ether of 1,6-hexane diol; or

or methacrylic acid esters wherein acrylates are replaced by methacrylates as exemplified by:

multifunctional acrylic acid ester acids such as trimethylol propane triacrylate, di trimethylol propane tetraacrylate, trimethylol ethane triacrylate, pentaerythritol triacrylate, pentaerythritol tetraacrylate, dipentaerythritol tetraacrylate, dipentaerythritol pentaacrylate, dipentaerythritol hexaacrylate, ∈-caprolactone adduct of dipentaerythritol hexaacrylate, pyrogallol triacrylate, propanoic acid/dipentaerythritol triacrylate, propanoic acid/dipentaerythritol tetraacrylate, hydroxy pivalylaldehyde denatured dimethylol propane triacrylate, or

methacrylic acids wherein these acrylates are replaced by methacrylates.

There is no particular restriction to the epoxy compound preferably used in the present invention, but the aromatic epoxide preferably used is exemplified by di- or poly-glycidyl ether produced by the reaction between the polyvalent phenol containing at least one aromatic nucleus or its alkylene oxide adduct and epichlorhydrin. It is exemplified by bisphenol A or di- or poly-glycidyl ether of its alkylene oxide adduct, and, hydrogen-added bisphenol A or di- or poly-glycidyl ether of its alkylene oxide adduct, and novolak type epoxy resin. In this case, the alkylene oxide is exemplified by ethylene oxide and propylene oxide. Further, the alicyclic epoxide is exemplified by the preferably used compound containing the cyclohexene oxide or cyclopentene oxide that is obtained by epoxidation of the compound containing at least one cycloalkane ring such as cyclohexene or cyclopentene ring, using an appropriate oxidizing agent such as hydrogen peroxide or peroxy acid. The preferably used aliphatic epoxide is exemplified by the aliphatic multi-valent alcohol or di- or poly-glycidyl ether of its alkylene oxide adduct. The typical examples are:

diglycidyl ether of alkylene glycolate such as diglycidyl ether of the ethylene glycolate, diglycidyl ether of propylene glycolate or diglycidyl ether of 1,6-hexanediol;

polyglycidyl ether of multi-valent alcohol such as

glycerine or di- or tri-glycidyl ether of its alkylene oxide adduct; and

diglycidyl ether of polyalkylene glycolate such as s polyethylene glycolate or the diglycidyl ether of its alkylene oxide adduct, and polypropylene glycolate or the diglycidyl ether of its alkylene oxide adduct.

In this case, the alkylene oxide is exemplified by ethylene oxide and propylene oxide. Two or more of them can be combined for use.

There is no particular restriction to the oxetane compound preferably used in the present invention. The examples are 3-hydroxymethyl-3-methyl oxetane, 3-hydroxymethyl-3-ethyloxetane, 3-hydroxymethyl-3-propyl oxetane, 3-hydroxymethyl-3-normal butyloxetane, 3-hydroxymethyl-3-phenyloxetane, 3-hydroxymethyl-3-benzyloxetane, 3-hydroxy ethyl-3-methyloxetane, 3-hydroxy ethyl-3-ethyloxetane, 3-hydroxy ethyl-3-propyl oxetane, 3-hydroxy ethyl-3-phenyloxetane, 3-hydroxy propyl-3-methyloxetane, 3-hydroxy propyl-3-ethyloxetane, 3-hydroxy propyl-3-propyl oxetane, 3-hydroxy propyl-3-phenyloxetane, and 3-hydroxy butyl-3-methyloxetane. Of these compounds, 3-hydroxymethyl-3-methyloxetane and 3-hydroxymethyl-3-ethyloxetane are preferably used as an oxetane mono alcohol compound. Because they are easy to procure.

The organic compound applicable to the plasma polymerized film of the present invention is exemplified by hydrocarbon, halogen-containing compound and nitrogen-containing compound.

Hydrocarbon is exemplified by ethane, ethylene, methane, acetylene, cyclo hexane, benzene, xylylene, phenylacetylene, naphthalene, propylene, campho, menthol, toluene and isobutylene.

The halogen-containing compound is exemplified by tetrafluoro methane, tetrafluoro ethylene, hexafluoro propylene, and fluoroalkyl methacrylate.

The nitrogen-containing compound is exemplified by pyridine, alylamine, butylamine, acrylonitryl, acetonitryl, benzonitryl, methacrylonitryl, and aminobenzene.

The following describes the organic metal compound of the present invention as one of the material components:

Commonly known organic metal compound can be used as the organic metal compound of the present invention as one of the material components. Of such components, the one expressed by following Formula (I) is preferably utilized:

R¹ₓMR²_{y}R³_{z} Formula (I)

wherein M denotes a metal (e.g., Li, Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Cd, In, Ir, Sn, Sb, Cs, Ba, La, Hf, Ta, W, Ti, Pb, Bi, Ce, Pr, Nd, Pm, Eu, Gd, Tb, Dy, Ho, Er, Tm, Yb, Lu), R¹ indicates an alkyl group, R² shows an alkoxy group, R³ shows a group selected from among the β-diketone coordinate group, β-ketocarboxylic acid ester coordinate group, β-ketocarboxylic acid coordinate group and ketoxy coordinate group. When the affinity unit of the metal M is “m”, x+y+z=m, x=0 through m, y=0 through m, and z=0 through m. They are 0 or a positive integer. At least one of x, y and z is not 0. The alkyl group of R¹ is exemplified by methyl group, ethyl group, propyl group and butyl group. The alkoxy group of R² is exemplified by methoxy group, ethoxy group, propoxy group, butoxy group, and 3,3,3-trifluoropropoxy group. The hydrogen atom of the alkyl group may be replace by a fluorine atom. The group selected from among β-diketone coordinate group, β-ketocarboxylic acid ester coordinate group, β-ketocarboxylic acid coordinate group and ketoxy coordinate group in R³ is such that the β-diketone coordinate group is exemplified by 2,4-pentanedione (also called acetyl acetone or acetoacetone), 1,1,1,5,5,5-hexamethyl-2,4-pentanedione, 2,2,6,6-tetramethyl-3,5-heptanedione, and 1,1,1-trifluoro-2,4-pentanedione. The β-ketocarboxylic acid ester coordinate group is exemplified by methyl acetoacetate ester, ethyl acetoacetate ester, propyl acetoacetate ester, ethyl trimethylacetoacetate, and methyl trifluoroacetoacetate. The β-ketocarboxylic acid coordinate group is exemplified by acetoacetic acid and trimethyl acetoacetic acid. The ketoxy is exemplified by acetooxy group (or acetoxy group), propionyloxy group, butyroxy group, acryloyl oxy group, and methacryloyloxy group. The number of the carbon atoms in these groups including the organic metal compounds in the aforementioned examples is preferably 18 or less. As shown in the examples, the straight chain or branched chain substance or hydrogen atom may be replaced by the fluorine atom.

In the present invention, from the viewpoint of handling, the organic metal compound free from concern about explosion is preferably used. The organic metal compound having one or more oxygen atoms in a molecule is preferably used. To put it more specifically, the organic metal compound containing at least one of the alkoxy groups of R² and the metal compound containing at least one of the groups selected from among the β-diketone coordinate group, β-ketocarboxylic acid ester coordinate group, β-ketocarboxylic acid coordinate group and ketoxy coordinate group in R³ are preferably used.

The following describes the specific examples of the organic metal compounds:

The organic silicon compound is exemplified by tetraethyl silane, tetramethyl silane, tetraisopropyl silane, tetrabutyl silane, tetraethoxy silane, tetraisopropoxy silane, tetrabutoxy silane, dimethyldimethoxy silane, diethyl diethoxy silane, diethyl silane di (2,4-pentane dionate), methyl trimethoxy silane, methyl triethoxy silane, ethyl triethoxy silane, 2-(3,4-epoxy cyclohexyl)ethyl trimethoxy silane, 3-glusidoxy propyl trimethoxy silane, 3-glusidoxy propyl methyl diethoxy silane, 3-glusidexypropyl triethoxy silane, p-styryl trimethoxy silane, 3-methacryloxy propyl methyldimethoxy silane, 3-methacryloxypropyltrimethoxy silane, 3-methacryloxy propyl methyl diethoxy silane, 3-methacryloxypropyltriethoxy silane, 3-acryloxypropyl trimethoxy silane, N-2 (aminoethyl) 3-aminopropyl methyldimethoxy silane, N-2 (aminoethyl) 3-aminopropyl trimethoxy silane, N-2 (aminoethyl) 3-aminopropyl ethoxy silane, 3-aminopropyl trimethoxy silane, 3-aminopropyl triethoxy silane, 3-triethoxysilyl-N-(1,3-dimethyl-butylidene) propyl amine, and N-phenyl-3-aminopropyl trimethoxy silane. They are preferably used in the present invention. Two or more of them can be combined for use at one time.

The organic titanium compound is exemplified by triethoxytitanium, trimethoxytitanium, triisopropoxytitanium, tributoxytitanium, tetraethoxytitanium, tetraisopropoxytitanium, methyldimethoxytitanium, ethyl triethoxytitanium, methyl triisopropoxytitanium, triethyltitanium, triisopropyl titanium, tributyltitanium, tetraethyltitanium, tetraisopropyl titanium, tetrabutyltitanium, tetradimethylaminotitanium, dimethyltitanium di(2,4-pentane dionate), ethyltitanium tri(2,4-pentane dionate), titanium tris(2,4-pentane dionate), titanium tris(acetomethylacetate), triacetoxytitanium, dipropoxypropionyloxy titanium and dibutyroxy titanium. They are preferably used in the present invention. Two or more of them can be combined for use at one time.

The organic tin compound is exemplified by tetraethyl tin, tetramethyl tin, di-n-butyl diacetate tin, tetrabutyl tin, tetraoctyl tin, tetraethoxy tin, methyl triethoxy tin, diethyl diethoxy tin, triisopropyl ethoxy tin, diethyl tin, dimethyl tin, diisopropyl tin, dibutyl tin, diethoxy tin, dimethoxy tin, diisopropoxy tin, dibutoxy tin, tin dibutylate, tin diacetoacetonate, ethyl tin acetoacetonate, ethoxy tin acetoacetonate, and dimethyl tin diacetoacetonate. They are preferably used in the present invention. Two or more of them can be combined for use at one time. The tin oxide film formed of these substances allows the specific resistance of the surface to be reduced below 1×10¹²Ω/□, and is preferably used as an antistatic layer.

Other organic metal compounds are exemplified by antimony ethoxide, arsenic triethoxide, barium 2,2,6,6-tetramethyl heptanedionate, beryllium acetyl acetonate, bithmuth hexafluoropentane dionate, dimethyl cadmium, calcium 2,2,6,6-tetramethyl heptanedionate, chromium trifluoropentane dionate, cobalt acetyl acetonate, copper hexafluoropentane dionate, magnesium hexafluoropentane dionate-dimethylether complex, gallium ethoxide, tetraethoxygermane, tetramethoxygermane, hafnium t-broxide, hafnium ethoxide, indium acetyl acetonate, indium 2,6-dimethylamino heptanedionate, ferrocene, lanthanum isopropoxide, lead acetate, tetraethyl lead, neodymium acetyl acetonate, platinum hexafluoropentane dionate, trimethylcyclopentadiethyl platinum, rhodium dicarbonylacetyl acetonate, strontium 2,2,6,6-tetramethyl heptanedionate, tantalum methoxide, tantalum trifluoroethoxide, tellurium ethoxide, tungusten ethoxide, vanadium triisopropoxideoxide, magnesium hexafluoroacetyl acetonate, zinc acetyl acetonate, and diethyl zinc.

Of the thin film forming gas introduced into the atmospheric pressure plasma space, electrical discharge gas is defined as a gas capable of causing plasma discharge, and serves as a medium to supply and receive energy. It is essential to cause plasma discharge. The electrical discharge gas is exemplified by nitrogen, rare gas and air. These substances can be used either independently or in combination as an electrical discharge gas. The Group XVIII elements of the Periodic Table as rare gases include helium, neon, argon, krypton, xenon and radon. In the present invention, nitrogen, argon and helium are preferably used as electrical discharge gas, more preferably nitrogen. The preferred amount of electrical discharge gas is 70 through 99.99% by volume with respect to the amount of the thin film forming gas to be supplied into the discharge space.

Additive gas is introduced for reaction and control of the membrane material. 0.001% by volume through 30% by volume of hydrogen, oxygen, nitrogen oxide, ammonium, hydrocarbons, alcohols, organic acids or water may be mixed with the aforementioned gas, and can be used as an additive gas. Of these substances, hydrocarbons, alcohols and organic acids are preferably used in the present invention. There is no particular restriction to hydrocarbons. Methane, ethane, propane, butane, pentane, hexane, heptane, octane and decane can be mentioned as examples. Methane is preferably used in particular. Methanol, ethanol and propanol can be mentioned as alcohols. Formic acid and acetic acid, acrylic acid, methacrylic acid and maleic acid can be mentioned as organic acids.

<<Atmospheric Pressure Plasma Method>>

The following describes the atmospheric pressure plasma method of the present invention:

The atmospheric pressure plasma method of the present invention is employed under atmospheric pressure or nearby pressure. The atmospheric pressure or nearby pressure is about 20 kPa through 110 kPa. The range from 93 kPa through 104 kPa is preferably used to get the satisfactory result described in the present invention.

The discharging conditions in the present invention are met by applying two or more electric fields having different frequencies to the discharge space, wherein the electric field obtained by superimposing the first high-frequency electric field and second high-frequency electric field is applied.

The frequency ω2 of the aforementioned second high-frequency electric field is higher than the aforementioned first high-frequency electric field frequency ω1; the relationship among the intensity V1 of the aforementioned first high-frequency electric field, the intensity V2 of the aforementioned second high-frequency electric field and the intensity IV of electric field for starting discharge meet the following expressions;

V1≧IV>V2 or V1>IV≧V2

and the output power density of the aforementioned second high-frequency electric field is 1 W/cm² or more.

High frequency can be defined as having at least 0.5 kHz frequency.

When both the high-frequency electric fields to be superimposed are sinusoidal waves, the component is the result of superimposing the frequency ω1 of the first high-frequency electric field and the frequency ω2 of the second high-frequency electric field which is higher than the aforementioned frequency ω1. The waveform is a sawtooth waveform formed by superimposing the higher sinusoidal wave of frequency ω2 on the sinusoidal wave of the frequency col.

In the present invention, the intensity of electric field for starting discharge the minimum intensity of the electric field that can cause electric discharge in the discharge space (such as electrode structure) used for actual thin film forming method and the reaction conditions (gas conditions, etc.). The intensity of electric field for starting discharge slightly differs according to the type of gas supplied to the discharge space, type of the electrode dielectric or the distance between electrodes. It depends on the intensity of electric field for starting discharge by electrical discharge gas when the discharge space is the same.

It is estimated that electric discharge capable of forming a thin film is generated by applying the aforementioned high-frequency electric field to the discharge space, whereby a high density plasma required to form a high-definition thin film is generated.

What is important in this case is that such a high-frequency electric field should be applied between the opposing electrode, namely, it should be applied to the same discharge space. A thin film of the present invention cannot be formed by the technique disclosed in the Unexamined Japanese Patent Application Publication No. 11-16696, wherein two electrodes to which electric field is applied are arranged, and different high-frequency electric fields are applied to each of the discrete and different discharge spaces.

The aforementioned description refers to the superimposition of the continuous wave such as sinusoidal wave. The present invention is not restricted thereto. For example, both can be pulse waves if one of them is a continuous wave and the other is a pulse wave. Further, the third electric field having different frequency can also be contained.

A specific way of applying the high-frequency electric field of the present invention to the same discharge space is to use a atmospheric pressure plasma discharge processing apparatus connected with the first power source for applying the first high-frequency electric field of frequency ω1 as the intensity V1 of electric field to the first electrode constituting the opposing electrodes, and with the second power source for applying the second high-frequency electric field of frequency ω2 as the intensity V2 of electric field.

The aforementioned atmospheric pressure plasma discharge processing apparatus has a gas supply section between the opposing electrodes to supply an electrical discharge gas and thin film forming gas. Further, it preferably contains an electrode temperature control device for controlling the electrode temperature.

A first filter is preferably connected to the first electrode, first power source or between them, and a second filter is preferably connected to the second electrode, second power source or between them. The first filter facilitates passage of the first high-frequency electric field current from the first power source to the first electrode, and connects the second high-frequency electric field current to the ground to hinder the passage of the second high-frequency electric field current from the second power source to the first power source. The second filter performs reverse function, namely, it facilitates passage of the second high-frequency electric field current from the second power source to the second electrode, and connects the first high-frequency electric field to the ground to hinder the passage of the first high-frequency electric field current from the first power source to the second power source. Hindering the passage in the sense in which it is used here refers to the act of allowing passage of preferably a maximum of only 20% of the current, more preferably a maximum of 10% of the current. Facilitating the passage refers to the act of allowing passage of preferably a minimum of 80% of the current, more preferably a minimum of 90% of the current.

For example, a capacitor of scores of pF through tens of thousands of pF or a coil of about a few μH can be used as the first filter in response to the frequency of the second power source. A coil of 10 μH or more is used as the second filter in response to the frequency of the first power source. Such a coil or capacitor can be used as a filter when connected to the ground through a capacitor.

Further, the first power source of the atmospheric pressure plasma discharge processing apparatus of the present invention preferably has a capacity to apply the intensity of electric field higher than that of the second power source.

In this case, the intensity of the electric field to be applied and the intensity of electric field for starting electric discharge as referred to in the present invention are defined as the values measured by the following method: Method of measuring the intensities V1 and V2 of electric field to be applied (unit: kV/mm):

Each electrode is provided with a high-frequency voltage probe (P6015A), and the output signal of the aforementioned high-frequency voltage probe is connected to an oscilloscope (TDS3012B manufactured by Tektronix) to measure the intensity of the electric field at a predetermined point of time.

Method of Measuring the Intensity of Electric Field for Starting Electric Discharge (unit: kV/mm):

An electrical discharge gas is supplied between the electrodes, and the intensity of electric field between the electrodes is increased. The intensity of the electric field for starting electric discharge is defined as the intensity of electric field for starting electric discharge IV. The measuring device is the same as that used to measure the intensity of the electric field to be applied.

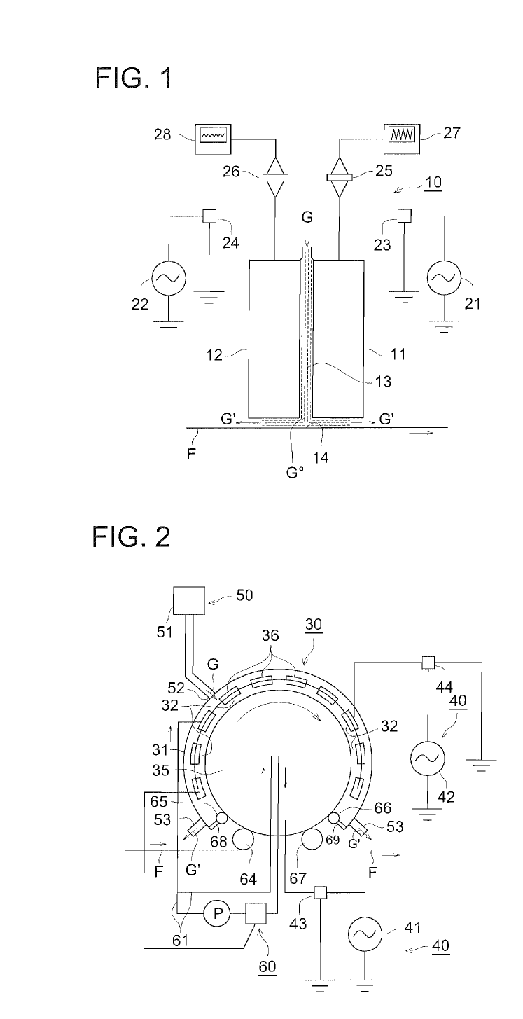

The position for measuring the aforementioned intensity of electric field by the high-frequency voltage probe used for measurement and the oscilloscope is shown in FIG. 1 (to be described later).

When the discharging conditions defined in the present invention are used, electric discharging can be started even by the electrical discharge gas having a higher intensity of electric field for starting electric discharge as in the case of nitrogen gas and a stable state of plasma of high density can be maintained, whereby a thin film of high performance can be formed.

In the aforementioned measurement, when a nitrogen gas is used as electrical discharge gas, the intensity of electric field for starting electric discharge IV (½ Vp−p) is about 3.7 kV/mm. Accordingly, in the aforementioned relationship, the first electric field having an intensity of V1≧3.7 kV/mm is applied, whereby nitrogen gas is excited to create a state of plasma.

In this case, the frequency of 200 kHz or less is preferably utilized as the frequency of the first power source. Further, either a continuous wave or pulse wave can be utilized for this electric field. The lower limit is preferably about 1 kHz.

In the meantime, the frequency of the second power source is preferably 800 kHz or more. As the frequency of the second power source is higher, a more compact and high-quality thin film of higher plasma density can be obtained. The upper limit is preferably about 200 MHz.

Application of a high-frequency electric field from such two power sources is essential to initiate electric discharge of electrical discharge gas having a high intensity of electric field for starting electric discharge, by the first high-frequency electric field. Further, the crucial point in the present invention is to form a compact and high-quality thin film by increasing the plasma density by the high frequency and high output power density of the second high-frequency electric field.

Increased output power density of the first high-frequency electric field enhances the output power density of the second high-frequency electric field with the uniformity of the electric discharge kept unchanged. This procedure provides more uniform plasma of higher density, and ensures compatibility between higher film making speed and enhanced membrane material quality.

In the atmospheric pressure plasma discharge processing apparatus of the present invention, as described above, electric discharging takes place between the opposing electrodes, and the gas introduced between the aforementioned opposing electrodes is formed into a state of plasma. A substrate placed between the aforementioned opposing electrodes or carried between the electrodes is exposed to the aforementioned plasmic gas, whereby a thin film is formed on the aforementioned substrate. Another type of atmospheric pressure plasma discharge processing apparatus is a jet type apparatus wherein, similarly to the aforementioned apparatus, electric discharging is caused between the opposing electrodes, and the gas introduced between the aforementioned opposing electrodes is excited, or is formed into a state of plasma. Thus the gas is excited and jetted out of the aforementioned opposing electrodes or plasmic gas is blown off so that a substrate (placed still or being carried) close to the aforementioned opposing electrodes is exposed thereto, whereby a thin film is formed on the aforementioned substrate.

FIG. 1 is a schematic view showing an example of a jet type atmospheric pressure plasma discharge processing apparatus preferably used in the present invention.

The jet type atmospheric pressure plasma discharge processing apparatus has a plasma discharge processing apparatus, a gas supply section and electrode temperature adjusting section (not illustrated in FIG. 1, but shown in FIG. 2), in addition to the electric field application section including two power sources.

The plasma discharge processing apparatus 10 has an opposing electrode made up of a first electrode 11 and second electrode 12. The first high-frequency electric field with the frequency ω1, the intensity V1 of electric field and current I1 from the first power source 21 is applied between the aforementioned opposing electrodes from the first electrode 11. The second high-frequency electric field with the frequency ω2, intensity V2 of electric field and current I2 from the second power source 22 is applied from the second electrode 12. The first power source 21 applies the high-frequency electric field (V1>V2) of higher the intensity than that of the second power source 22, wherein the first frequency ω1 of the first power source 21 is lower than the second frequency ω2 of the second power source 22.

A first filter 23 is installed between the first electrode 11 and first power source 21 to facilitate passage of a current from the first power source 21 to the first electrode 11, and the current from the second power source 22 is connected to the ground to hinder the passage of a current from the second power source 22 to the first power source 21. A second filter 24 is installed between the second electrode 12 and second power source 22 to facilitate passage of a current from the second power source 22 to the second electrode, and the current from the first power source 21 is connected to the ground to hinder passage of a current from the first power source 21 to the second power source.

The aforementioned thin film forming gas G is introduced between the opposing electrodes (discharge space) 13 of the first electrode 11 and second electrode 12 from the gas supply section as shown in FIG. 2 (to be shown later). The aforementioned high-frequency electric field is applied between the first electrode 11 and second electrode 12 by the first power source 21 and second power source 22 so that electric discharging is caused. With the aforementioned thin film forming gas G formed into the state of plasma, a jet of gas is blown against the lower side of the opposing electrode (bottom side of paper). The processing space created by the bottom surface of the opposing electrodes and the substrate F is filled with plasmic gas G°. A thin film is formed on the substrate F unwound and fed from the unwinder of the substrate (not illustrated) or fed from the previous process, close to the processing position 14. While the thin film is formed, a medium goes through the tube from the electrode temperature adjusting section as shown in FIG. 2 (to be shown later) heats and cools the electrode. The physical properties and composition of the obtained thin film may be changed by the substrate temperature during plasma discharge processing. It is preferred that appropriate measures should be taken to prevent this. An insulating material such as distilled water or oil is preferably used as a temperature adjusting medium. The temperature inside the electrode is preferably adjusted to uniform level in order to minimize uneven temperature in the lateral and longitudinal directions of the substrate at the time of plasma discharge processing.

FIG. 1 shows the measuring instrument and measuring position used to measure the intensity of the electric field to be applied, and the intensity of electric field for starting electric discharging. Reference numerals 25 and 26 show a high-frequency voltage probe, and 27 and 28 denote an oscilloscope.

A plurality of the jet type atmospheric pressure plasma discharge processing apparatuses are arranged in parallel with the conveyance direction of the substrate F. Simultaneous electric discharging of the same plasmic gas allows a plurality of thin film layers to be formed at one and the same position. This arrangement ensures formation of thin films having a desired film thickness in a shorter time. Further, a plurality of the apparatuses are arranged in parallel with the conveyance direction of the substrate F. Each apparatus is provided with a different thin film forming gas, and a different plasmic gas is jetted out. This provides lamination of thin films with different layers.

FIG. 2 is a schematic view showing an example of the atmospheric pressure plasma discharge processing apparatus for processing a substrate between opposing electrodes preferably used in the present invention.

The atmospheric pressure plasma discharge processing apparatus of the present invention includes at least a plasma discharge processing apparatus 30, an electric field application section 40 containing two power sources, a supply section 50, and an electrode temperature adjusting section 60.

A thin film is formed by plasma discharge processing of the substrate F between the opposing electrodes 32 (the position between the opposing electrode is also referred to as “discharge space” 32) between the roll rotating electrode (first electrode) 35 and rectangular fixed electrode group (second electrode) (rectangular fixed electrode group is hereinafter referred to as “fixed electrode group”) 36.

In the discharge space 32 formed between the roll rotating electrode 35 and fixed electrode group 36, the first high-frequency electric field of frequency ω1, the intensity V1 of electric field and current I1 is applied to the roll rotating electrode 35 from the first power source 41, and the second high-frequency electric field of frequency ω2, intensity V2 of electric field and current I2 is applied to the fixed electrode group 36 from the second power source 42.

A first filter 43 is placed between the roll rotating electrode 35 and first power source 41. The first filter 43 facilities passage of a current from the first power source 41 to the first electrode. The current from the second power source 42 is connected to the ground to inhibit passage of a current from the second power source 42 to the first power source. Further, a second filter 44 is installed between the fixed electrode group 36 and second power source 42, and the second filter 44 facilities passage from the second power source 42 to the second electrode. The current from the first power source 41 is connected to the ground to inhibit passage of a current from the first power source 41 to the second power source.

In the present invention, the roll rotating electrode 35 can be used as the second electrode, and the rectangular fixed electrode group 36 can be used as the first electrode. In any case, the first electrode is connected with the first power source and the second electrode is connected with the second power source. The first power source preferably applies a high-frequency electric field (V1>V2) of the intensity higher than that of the second power source. Further, the frequency is capable of being ω<ω2.

The current is preferably I1<I2. The current I1 of the first high-frequency electric field is preferably 0.3 mA/cm² through 20 mA/cm², more preferably 1.0 mA/cm² through 20 mA/cm². Further, the current I2 of the second high-frequency electric field is preferably 10 mA/cm² through 100 mA/cm², more preferably 20 mA/cm² through 100 mA/cm².

The flow rate of the thin film forming gas G generated by the gas generating apparatus 51 of the gas supply section 50 is controlled by the gas flow rate adjusting device (not illustrated) and the gas G is introduced into a plasma discharge processing container 31 through a gas inlet 52.

The substrate F is unwound and fed from a unwinder (not illustrated) or is fed from the previous process in the arrow-marked direction. It is fed through a guide roll 64, and shuts off air and other gas entrained by a nip roll 65. Being wound and rotated in contact with a roll rotating electrode 35, it is fed between the rectangular fixed electrode group 36.

During the conveyance, electric field is applied from both the roll rotating electrode 35 and fixed electrode group 36, and electric discharge plasma is produced between the opposing electrodes (discharge space) 32. The substrate F is wound and rotated in contact with the roll rotating electrode 35, and a thin film is formed by the plasmic gas.

A plurality of rectangular stationary number of electrodes are arranged on the circumference larger than that of the aforementioned roll electrode. The discharge area of the aforementioned electrode is expressed by the sum of the areas on the surface face to face with the roll rotating electrode 35 of all the rectangular stationary electrodes arranged face to face with the roll rotating electrode 35.

The substrate F is wound by a winder (not illustrated) through a nip roll 66 and guide roll 67 or is sent to the next process.

The processed exhaust gas G′ subjected to electric discharging is discharged from the exhaust outlet 53.

In order to heat or cool the roll rotating electrode 35 and fixed electrode group 36 during the formation of a thin film, a medium whose temperature has been adjusted by an electrode temperature adjusting section 60 is fed to both electrodes by a liquid feed pump P through a tube 61, so that the temperature is adjusted from inside the electrode. The reference numerals 68 and 69 denote a partition plate that separates the plasma discharge processing container 31 from the external world.

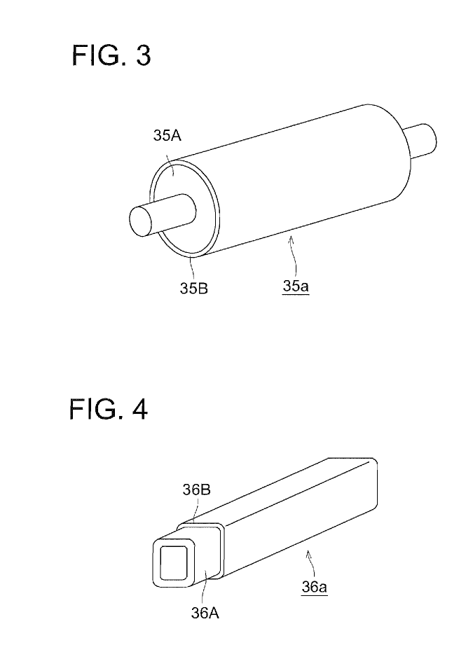

FIG. 3 is a perspective view representing an example of the structure of the conductive metallic base material of a roll rotating electrode of FIG. 2 and the dielectric covering the same;

In FIG. 3, the roll electrode 35a is made up of a conductive metallic base material 35A and a dielectric 35B covering the same from above. To control electrode surface temperature during the plasma discharging and to keep the surface temperature of the substrate F at a predetermined value, means are provided to permit circulation of a temperature adjusting medium (e.g., water or silicone oil).

FIG. 4 is a perspective view representing an example of the structure of the conductive metallic base material of a rectangular electrode and the dielectric covering the same;

In FIG. 4, the rectangular electrode 36a is made of a conductive metallic base material 36A covered by the dielectric 36B, similarly to the case of FIG. 3. The aforementioned electrode is formed as a metallic pipe, which served as a jacket to adjust the temperature for electric discharging

The rectangular electrode 36a of FIG. 4 can be a cylindrical electrode. As compared with the cylindrical electrode, the rectangular electrode has the effect of expanding the range of electric discharging (discharge area), and therefore, it is preferably used in the present invention.

In FIGS. 3 and 4, after ceramics as dielectrics 35B and 36B are thermally sprayed onto the conductive metallic base materials 35A and 36A respectively, the roll electrode 35a and rectangular electrode 36a are provided with pore sealing, using the pore sealing material of inorganic compound. The covering of the ceramic dielectric should be about 1 mm thick on one side. Alumina/silicon nitride is preferably used as the ceramic material to be thermally sprayed. In particular, alumina is more preferably used since it can be easily processed. The dielectric layer can be a dielectric provided with lining treatment wherein inorganic material is arranged by lining.

The conductive metallic base materials 35A and 36A are exemplified by such a metal as a titanium metal or titanium alloy, silver, platinum, stainless steel, aluminum and iron, a composite material between iron and ceramic, and a composite material between aluminum and ceramic. The titanium metal or titanium alloy is preferable in particular for the reasons to be discussed later.

The distance between the opposing first and second electrodes is defined as the minimum distance between the aforementioned dielectric surface and the conductive metallic base material surface of the other electrode, when one of the electrodes is provided with a dielectric. When both electrodes are provided with dielectrics, it is defined as the minimum distance between dielectric surfaces. The distance between electrodes is determined by giving consideration to the thickness of the dielectric provided on the conductive metallic base material, the intensity of the electric field to be applied, and the object of using plasma. In any case, to ensure uniform electric discharge, this distance is preferably 0.1 through 20 mm, more preferably 0.5 through 2 mm.

The details of the conductive metallic base material and dielectric preferably used in the present invention will be described later.

The Pyrex (registered trademark) glass-made processing container is preferably used as the plasma discharge processing container 31. If insulation with the electrode is provided, a metallic product can also be used. For example, the inner surface of the aluminum or stainless steel frame may be stuck to a polyimide resin. The aforementioned metal frame may be thermally sprayed with ceramic to provide insulation. In FIG. 1, both sides of the two parallel electrodes (up to close to the substrate surface) are preferably covered with the aforementioned material.

The following commercially available products can be used as the first power source (high frequency power source) installed on the atmospheric pressure plasma discharge processing apparatus of the present invention:

| Power source for | | | | |
|---|---|---|---|---|
| application | Manufacturer | Frequency | | Product name |
| A1 | Shinko Electric | 3 | kHz | SPG3-4500 |
| A2 | Shinko Electric | 5 | kHz | SPG5-4500 |
| A3 | Kasuga Electric | 15 | kHz | AGI-023 |
| A4 | Shinko Electric | 50 | kHz | SPG50-4500 |
| | Co., Ltd. | | | |
| A5 | Heiden Research | 100 | kHz * | PHF-6k |
| | Laboratory | | | |
| A6 | Pearl Industry | 200 | kHz | CF-2000-200k |
| A7 | Pearl Industry | 400 | kHz | CF-2000-400k |

The following commercially available products can be used as the second power source (high frequency power source):

| Power source for | Symbol | | | |
|---|---|---|---|---|
| application | Manufacturer | Frequency | | Product name |
| B1 | Pearl Industry | 800 | kHz | CF-2000-800k |
| B2 | Pearl Industry | 2 | MHz | CF-2000-2M |
| B3 | Pearl Industry | 13.56 | MHz | CF-5000-13M |
| B4 | Pearl Industry | 27 | MHz | CF-2000-27M |
| B5 | Pearl Industry | 150 | MHz | CF-2000-150M |

Any of them can be used preferably.

Of the aforementioned power sources, the ones marked with an asterisk indicate an impulse high frequency power source (100 kHz in the continuous mode) manufactured by Heiden Research Laboratory. Others are high frequency power sources capable of applying only the continuous sinusoidal wave.

In the present invention, the atmospheric pressure plasma discharge processing apparatus is preferred to use the electrode capable of maintaining the state of uniform and stable electric discharging by application of the aforementioned electric field.

In the electric power for application of electric field between the opposing electrodes of the present invention, an electric power (output power density) of 1 W/cm² or more is supplied to the second electrode (second high-frequency electric field). It excites the electrical discharge gas to generate plasma and to afford energy to a thin film forming gas, whereby a thin film is formed. The upper limit value of electric power supplied to the second electrode is preferably 50 W/cm², more preferably 20 W/cm². The lowest limit value is preferably 1.2 W/cm². It should be noted, however, that discharge area (cm²) refers to the area in the range wherein electric discharging occurs between the electrodes.

When an electric power (output power density) of 1 W/cm² or more is supplied to the first electrode (first high-frequency electric field), the output power density is improved without the uniformity of the second high-frequency electric field being deteriorated. This arrangement generates further uniform and high-density plasma and ensures compatibility between a further increase in the film making speed and further improvement of the membrane material. The electric power is preferably 5 W/cm² or more. The upper limit value of the electric power supplied to the first electrode is preferably 50 W/cm².

There is no particular restriction to the waveform of the high-frequency electric field. There are a continuous sinusoidal wave-like continuous oscillation mode called a continuous mode, and a intermittent oscillation mode for performing intermittent ON/OFF operations called a pulse mode. Either of them can be used. The continuous sinusoidal wave is preferably used at least on the second electrode (second high-frequency electric field) in order to produce a more closely packed and high-quality film.

The electrode used in the thin film forming method based on atmospheric pressure plasma described above is required to meet severe working conditions both in structure and performance. To meet this requirement, an electrode is preferably made of the metallic base material covered with a dielectric.

The dielectric-covered electrode used in the present invention is required to have characteristics conforming to various forms of metallic base materials and dielectrics. One of such characteristics is such a combination that ensures the difference in the linear thermal coefficient of expansion between the metallic base material and dielectric is 10×10⁻⁶/° C. or less. This difference is preferably 8×10⁻⁶/° C. or less, more preferably 5×10⁻⁶/° C. or less, still more preferably 2×10⁻⁶/° C. or less. The linear thermal coefficient of expansion in the sense in which it is used here refers to the physical properties specific to a known material.

The following shows combinations between the conductive metallic base materials and dielectrics wherein the difference in the linear thermal coefficient of expansion is kept within the aforementioned range:

1: The metallic base material is made of pure titanium or titanium alloy, and the dielectric is made of ceramic thermally sprayed coating.

2: The metallic base material is made of pure titanium or titanium alloy, and the dielectric is made of glass lining.

3: The metallic base material is made of stainless steel and the dielectric is made of ceramic thermally sprayed coating.

4: The metallic base material is made of stainless steel and the dielectric is made of glass lining.

5: The metallic base material is made of a composite material of ceramic and iron, and the dielectric is made of ceramic thermally sprayed coating.

6: The metallic base material is made of a composite material of ceramic and iron, and the dielectric is made of glass lining.

7: The metallic base material is made of a composite material of ceramic and aluminum, and the dielectric is made of ceramic thermally sprayed coating.

8: The metallic base material is made of a composite material of ceramic and aluminum, and the dielectric is made of glass lining.

From the viewpoint of the difference in linear thermal coefficient of expansion, the aforementioned items 1 or 2 and 5 through 8 are preferably used. Item 1 is preferably used in particular.

In the present invention, from the viewpoint of the aforementioned characteristics, titanium or titanium alloy is preferably used in particular as the metallic base material. When the titanium or titanium alloy is used as the metallic base material, and the aforementioned material is used as the dielectric, it is possible to ensure a long-time use under severe conditions, free from deterioration of the electrode, cracks, peeling, disengagement or other defects during use.

The metallic base material of the electrode preferably used in the present invention is a titanium alloy or titanium metal containing 70% or more by mass of titanium. In the present invention, the titanium alloy or titanium metal can be used without any problem if the amount of titanium contained therein is 70% or more by mass. The amount of titanium contained is preferably 80% or more by mass of titanium. Pure titanium for industrial use and corrosion-resistant titanium, generally used as high-strength titanium and others are used as the titanium alloy or titanium metal preferably used in the present invention. TIA, TIB, TIC and TID can be mentioned as the pure titanium for industrial use. They contain a small amount of iron atom, carbon atom, nitrogen atom, oxygen atom, and hydrogen atom, and contain 99% or more by mass of titanium. T15PB is preferably used as a corrosion resistant titanium alloy. Lead is included in addition to the aforementioned atoms contained, and the amount of contained titanium is 98% or more by mass. The T64, T325, T525 and TA3 including vanadium and tin in addition to the aforementioned atoms except for lead are preferably used as titanium alloy. The amount of titanium contained therein is 85% or more by mass. In the aforementioned titanium alloy or titanium metal, thermal coefficient of expansion is smaller than that of the stainless steel, for example, AISI316 by about ½. A combination of the dielectric (to be described later) provided on the titanium alloy or titanium metal is preferable for the metallic base material, which can be used at a high temperature for a long time.

To put it more specifically, to meet the requirements, the dielectric is preferably an inorganic compound having a relative dielectric constant of 6 through 45. Such a dielectric is exemplified by a ceramic such as alumina and silicon nitride, or a glass lining material such as silicate based glass and borate based glass. Among them, the material spayed with ceramic (to be described later) or the material provided with glass lining are preferably used. Especially the dielectric provided by thermal spraying of aluminum is preferred.

One of the specification to withstand large electric power is that the void ratio of the dielectric is 10% or less by volume, preferably 8% or less by volume, more preferably greater than 0% without exceeding 5% by volume. The void ratio of the dielectric can be measured by the BET adsorption method and mercury porosimeter. In the Example (to be described later), the void ratio is measured by the mercury porosimeter manufactured by Shimazu Seisakusho Ltd., using the fragment of the dielectric coated with the metallic base material. When the dielectric has a lower void ratio, high durability can be achieved. The dielectric of lower void ratio having such a void can be produced, for example, by ceramic thermally sprayed coating of high density and close adhesion provided by the atmospheric pressure plasma spraying method (to be described later) and others. Further, to reduce the void ratio, pore sealing is preferably provided.

The aforementioned atmospheric pressure plasma spraying method is a technique of forming a film by putting fine particles of ceramic, wire and others into the plasma heat source and by blowing the molten and semi-molten particles against the metallic base material to be coated. The plasma heat source is a high-temperature plasma gas generated by heating the molecular gas to a high temperature, dissociating the atom, and giving energy to release electrons. The jetting speed of this plasma gas is high. As compared with the conventional arc spraying and frame spraying, spraying material collides with the metallic base material at a high speed, and hence, coating of close adhesion and high density can be obtained. Details are described in the Unexamined Japanese Patent Application Publication No. 2000-301655 that discloses the thermal spraying method for forming a heat shielding coating on the high-temperature exposed member. This method provides the aforementioned void ratio of the dielectric for coating (ceramic thermal spray-coated film).

Another specification to withstand a high level of electric power is that the dielectric is 0.5 through 2 mm thick. The fluctuation in film thickness is preferably 5% or less, preferably 3% or less, still more preferably 1% or less.

To reduce the void ration of the dielectric further, the aforementioned thermal spray-coated film such as ceramic should be provided with pore sealing, using the inorganic compound. Metallic oxide is preferably used as the aforementioned inorganic compound. Of these, the material containing silicon oxide (SiOx) as the main component is preferably used.

The inorganic compound provided with pore sealing is cured and formed by sol-gel reaction. When the inorganic compound provided with pore sealing mainly contains metallic oxide, metallic alkoxide or the like is coated on the aforementioned ceramic thermal spray-coated film as sealing liquid, and is cured by sol-gel reaction. When the inorganic compound mainly contains silica, alkoxy silane is preferably used as the sealing liquid.

To promote the sol-gel reaction, energy processing is preferably used. The method of energy processing includes the technique of heat curing (preferably 200° C. or less) and application of ultraviolet. Further, in the step of pore sealing, sealing liquid is diluted, coating and curing operations are repeated sequentially several times. This arrangement enhances mineralization, and provides a compact electrode free from deterioration.

In the present invention, the metallic alkoxide of the dielectric-covered electrode as a sealing liquid has been coated on the ceramic thermal spray-coated film. After that, pore sealing is performed wherein curing is provided by sol-gel reaction. In this case, the amount of the metallic oxide after being cured is preferably 60 mol % or more. When alkoxy silane is used as the metallic alkoxide which is a sealing liquid, the amount of SiOx (“x” denotes 2 or less) contained after curing is preferably 60 mol % or more. The amount of SiOx contained after curing is measured by analyzing the fault of the dielectric layer according to the XPS (X-ray photoelectron spectroscopy)

In the thin film forming method of the present invention, the electrode is adjusted in such a way that the maximum height (Rmax) of the surface roughness specified by the JIS B0601 at least on the side in contact with the substrate of the electrode is 10 μm or less. This is preferred from the viewpoint of obtaining the effect described in the present invention. The maximum value of the surface roughness is more preferred 8 μm or less, and still more preferably 7 μm or less. The thickness of the dielectric and the gap between the electrodes can be keep constant by grind-finishing the dielectric surface of such a dielectric-covered electrode, whereby the state of electric discharge can be stabilized. This arrangement further eliminates the possibility of distortion and cracks caused by the difference in thermal shrinkage or residual stress, and substantially improves the precision and durability. Grind-finishing of the dielectric surface is preferably performed at least on the side in contact with the substrate. Further, the average surface roughness (Ra) of the centerline specified in the JIS B0601 is preferably 0.5 μm or less, more preferably 0.1 μm or less.

In the dielectric-covered electrode used in the present invention another preferred specification for withstanding large electric power is that the heat-resistant temperature is 100° C. or more, more preferably 120° C. or more, still more preferably 150° C. or more in particular. The upper limit is 500° C. The heat-resistant temperature denotes the maximum temperature wherein normal electric discharging is possible without dielectric breakdown occurring in the voltage used in the step of processing the atmospheric pressure plasma. Such a heat-resistant temperature can be achieved by the appropriate combination of the aforementioned ceramic thermal spraying method, application of the dielectric provided by the lamellar glass linings wherein the amounts of bubbles contained therein are different, and appropriate selection of the material within the range of the difference in the linear thermal coefficient of expansion between the aforementioned metallic base material and the dielectric.

<<Inorganic Film>>

The following describes the inorganic film used in the present invention.

The inorganic film of the present invention is a film having the effect of mainly blocking such a gas as moisture and oxygen. At least one of the layers of the inorganic film is mainly made up of metal oxide, metal nitride-oxide or metal nitride. In this layer, the percentage of the metal atoms (e.g., Li, Be, B, Na, Mg, Al, Si, K, Ca, Sc, Ti, V, Cr, Mn, Fe, Co, Ni, Cu, Zn, Ga, Ge, Rb, Sr, Y, Zr, Nb, Me, Cd, In, Ir, Sn, Sb, Cs, Ba, La, Hf, Ta, W, Tl, Pb, Bi, Ce, Pr, Nd, Pm, Eu, Gd, Tb, Dy, Ho, Er, Tm, Yb, Lu, etc.) contained in this film exceeds 5% in terms of density expressed by the number of atoms, preferably 10% or more, more preferably 20% or more. The density of the metal atom in the inorganic film can be measured by the XPS surface analyzer. Further, the inorganic film of the present invention is preferably made up mainly of ceramic components such as metal oxide, metal nitride-oxide and metal nitride formed of the aforementioned metal elements. The percentage of the carbon contained is preferably 1% or less. There is no particular restriction to the film thickness, which is approximately 1 through 10000 nm, preferably 5 through 1000 nm in particular.

The method of forming the inorganic film of the present invention is exemplified by a wet process such as coating, as well as a dry process such as a vacuum film forming method (e.g., vapor deposition, sputtering, plasma CVD, and ion plating), and atmospheric pressure plasma method. There is no particular restriction to the forming method. To form a compact inorganic film of high gas barrier functions, the dry process is preferably used, and atmospheric pressure plasma method is more preferably used.

The thin film forming method disclosed in the Unexamined Japanese Patent Application Publication No. 10-154598, Unexamined Japanese Patent Application Publication No. 2003-49272, and WO02/048428 (leaflet) can be employed as the atmospheric pressure plasma method for forming an inorganic film of the present invention. The same atmospheric pressure plasma method as the method of forming the aforementioned plasma polymerized film, and the thin film forming method disclosed in the Unexamined Japanese Patent Application Publication No. 2004-68143 are preferably employed to form a compact inorganic film of high gas barrier functions. Especially the atmospheric pressure plasma method similar to the method of forming the aforementioned plasma polymerized film is preferably utilized to unwind the web-like substrate from a roll-like unwinder, to form a stress relaxation film and inorganic film on a continuous basis and to wind them in the form of a roll.

Further, the material of the inorganic film (thin film forming component) capable of using the atmospheric pressure plasma method of the present invention is exemplified by an organic metal compound, halogen metal compound and metal hydride compound. The organic metal compound preferably used in the present invention is exemplified by the one specified by the aforementioned Formula (I).

The organic metal compound can be specifically exemplified by the same compounds as organic metal compounds employed to manufacture the aforementioned plasma polymerized film.

The silicon compound is exemplified by an organic silicon compound, silicon hydrogen compound, and halogenated silicon. The organic silicon compound is exemplified by tetraethyl silane, tetramethyl silane, tetraisopropyl silane, tetrabutyl silane, tetraethoxy silane, tetraisopropoxy silane, tetrabutoxy silane, dimethyldimethoxy silane, diethyl diethoxy silane, diethyl silane di-(2,4-pentane dionate), methyl trimethoxy silane, methyl triethoxy silane, and ethyl triethoxy silane. The silicon hydrogen compound is exemplified by tetrahydrogenated silane and hexahydrogenated disilane. The halogenated silicon compound is exemplified by tetrachloro silane, methyl trichloro silane, and diethyldichloro silane. They can all be used preferably in the present invention. Two or more of them can be mixed for use.

The titanium compound is exemplified by organic titanium compound, titanium hydrogen compound, and halogenated titanium. The organic titanium compound is exemplified by triethoxy titanium, trimethoxy titanium, triisopropoxy titanium, tributoxy titanium, tetraethoxy titanium, tetraisopropoxy titanium, methyldimethoxy titanium, ethyl triethoxy titanium, methyl triisopropoxy titanium, triethyl titanium, triisopropyl titanium, tributyl titanium, tetraethyl titanium, tetraisopropyl titanium, tetrabutyl titanium, tetradimethylamino titanium, dimethyl titanium di (2,4-pentane dionate), ethyl titanium tri (2,4-pentane dionate), titanium tris (2,4-pentane dionate), titanium tris (acetomethylacetate), triacetoxy titanium, dipropoxypropionyloxy titanium and dibutyroxy titanium. The titanium hydrogen compound is exemplified by a mono titanium hydrogen compound and dititanium hydrogen compound. The halogenated titanium is exemplified by trichloro titanium, and tetrachloro titanium. They can all be used preferably in the present invention. Two or more of them can be mixed for use.

The tin compound is exemplified by an organic tin compound, tin hydride compound, and halogenated tin. The organic tin compound is exemplified by tetraethyl tin, tetramethyl tin, di-n-butyl tin diacetate, tetrabutyl tin, tetraoctyl tin, tetraethoxy tin, methyl triethoxy tin, diethyl diethoxy tin, triisopropyl ethoxy tin, diethyl tin, dimethyl tin, diisopropyl tin, dibutyl tin, diethoxy tin, dimethoxy tin, diisopropoxy tin, dibutoxy tin, tin dibutylate, tin diacetoacetonate, ethyl tin acetoacetonate, ethoxy tin acetoacetonate and dimethyl tin diacetoacetonate. Tin hydrides are also exemplified. The halogenated tin is exemplified by tin dichloride and tin tetrachloride. They can all be used preferably in the present invention. Two or more of them can be mixed for use. The specific surface resistance of the tin oxide film formed by those substances can be reduced to 1×10¹²Ω/□ or less, and therefore, this tin oxide film is preferably employed as an antistatic layer.

Other organic metal compounds are exemplified by antimony ethoxide, arsenic triethoxide, barium 2,2,6,6-tetramethyl heptanedionate, beryllium acetyl acetonate, bithmuth hexafluoropentane dionate, dimethyl cadmium, calcium 2,2,6,6-tetramethyl heptanedionate, chromium trifluoropentane dionate, cobalt acetyl acetonate, copper hexafluoropentane dionate, magnesium hexafluoropentane dionate-dimethylether complex, gallium ethoxide, tetraethoxygermane, tetramethoxygermane, hafnium t-broxide, hafnium ethoxide, indium acetyl acetonate, indium 2,6-dimethylamino heptanedionate, ferrocene, lanthanum isopropoxide, lead acetate, tetraethyl lead, neodymium acetyl acetonate, platinum hexafluoropentane dionate, trimethylcyclopentadiethyl platinum, rhodium dicarbonylacetyl acetonate, strontium 2,2,6,6-tetramethyl heptanedionate, tantalum methoxide, tantalum trifluoroethoxide, tellurium ethoxide, tungusten ethoxide, vanadium triisopropoxideoxide, magnesium hexafluoroacetyl acetonate, zinc acetyl acetonate, and diethyl zinc.

<<Adhesive Film>>

The following describes the adhesive film used in the present invention.

The adhesive film used in the present invention is provided mainly between the stress relaxation film and inorganic film and is used to improve the adhesiveness between stress relaxation film and inorganic film. It is preferably a film containing an inorganic component included in the inorganic film, and an organic component having affinity for stress relaxation film. It is preferably the metal oxide, metal nitride-oxide, or metal nitride containing 1 through 50% carbon component. There is no particular restriction to film thickness, which is approximately 0.1 through 1000 nm, preferably 1 through 500 nm.

The material of the adhesive film (thin film forming component) used in the present invention can be an appropriate mixture of the organic compound used to form the aforementioned stress relaxation film, the organic metal compound used to form an inorganic film, the halogen metal compound, the metal hydride compound and the like. A coupling agent such as a silane coupling agent can be preferably used.

The silane coupling agent of the present invention is exemplified by 2-(3,4-epoxy cyclohexyl)ethyl trimethoxy silane, 3-glusidoxy propyl trimethoxy silane, 3 glusidoxy propyl methyl diethoxy silane, 3-glusidexypropyl triethoxy silane, p-styryl trimethoxy silane, 3-methacryloxy propyl methyldimethoxy silane, 3-methacryloxypropyl trimethoxy silane, 3-methacryloxy propyl methyl diethoxy silane, 3-methacryloxypropyl triethoxy silane, 3-acryloxypropyl trimethoxy silane, N-2 (aminoethyl) 3-aminopropyl methyldimethoxy silane, N-2 (aminoethyl) 3-aminopropyl trimethoxy silane, N-2 (aminoethyl) 3-aminopropylethoxy silane, 3-aminopropyl trimethoxy silane, 3-aminopropyl triethoxy silane, 3-triethoxysilyl-N-(1,3-dimethyl-butylidene) propyl amine, and N-phenyl-3-aminopropyl trimethoxy silane, without the present invention being restricted thereto.

The method of forming an adhesive film of the present invention is exemplified by a wet process such as coating, and a dry process such as a vacuum film forming method (e.g., vapor deposition, sputtering, plasma CVD, and ion plating) and atmospheric pressure plasma method. There is no particular restriction to the forming method. Especially the atmospheric pressure plasma method is preferably utilized to unwind the web-like substrate from a roll-like unwinder, to form a stress relaxation film and inorganic film on a continuous basis and to wind them in the form of a roll.

The atmospheric pressure plasma method used to form an adhesive film of the present invention can be exemplified by the method for forming the aforementioned stress relaxation film.

To ensure a desired permeation of moisture, oxygen and the like by such a structure of stress relaxation film/inorganic film/stress relaxation film, the gas barrier thin film laminate of the present invention can be formed by alternately laminating a plurality of inorganic films and stress relaxation films. This arrangement provides a gas barrier thin film laminate of excellent gas barrier performances free from deterioration due to bending.

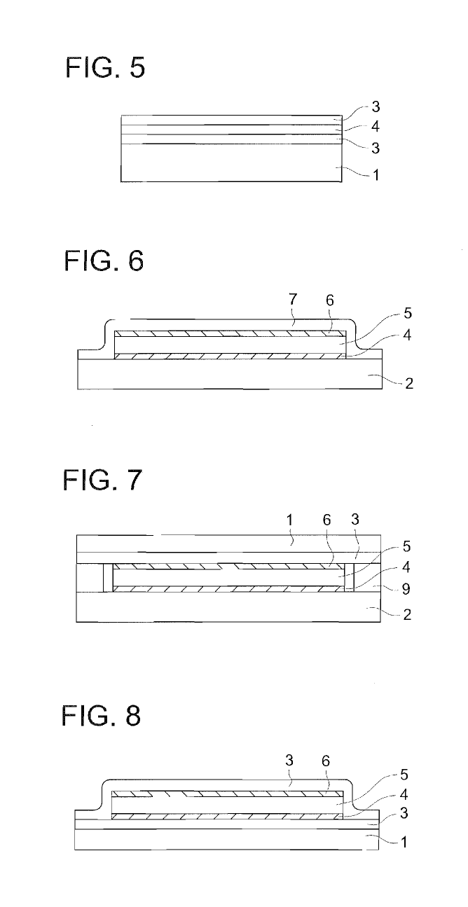

FIG. 5 is a cross sectional view showing an example of the structure of the gas barrier resin substrate made up of a resin substrate/stress relaxation film/inorganic film/stress relaxation film (wherein the stress relaxation film is 200 nm thick and inorganic film is 50 nm thick). The stress relaxation film 3a, inorganic film 3b and stress relaxation film 3a are sequentially laminated on the resin substrate 1.

The gas barrier resin substrate of the present invention is only required to meet the condition that the aforementioned gas barrier thin film laminate is provided on at least one of the surfaces of the resin substrate. There is no particular restriction to the application thereof. The gas barrier thin film laminate of the present invention is formed directly on the resin substrate or through the functional film (adhesive film, hard coated film, antireflection film, antistatic film, damage resistant film, lubricant film, smooth film, reflective film, etc.). Then this substrate can be used as a gas barrier resin substrate. It can be used as a sealing film for the device that is vulnerable to gas such as moisture or oxygen, such as the OLED and others on the substrate such as glass that does not allow passage of a gas such as moisture or oxygen. This arrangement provides a resin substrate of excellent gas barrier function impervious to bending.

There is no restriction as to the substrate used as the gas barrier resin substrate of the present invention. It is preferred to be a transparent resin substrate, and is exemplified by cellulose ester such as cellulose triacetate, cellulose diacetate, cellulose acetate propionate or cellulose acetatebutylate; polyester such as polyethylene terephthalate and polyethylene naphthalate; polyolefin such as polyethylene and polypropylene; as well as polyvinylidene chloride, polyvinyl chloride, polyvinyl alcohol, ethylenevinyl alcohol copolymer, syndiotactic polystyrene, polycarbonate, norbornane based resin, polymethylpentene, polyetherketone, polyimide, polyether sulfone, polysulfone, polyetherimide, polyamide, fluorine resin, polymethylacrylate, and acrylate copolymer. These substances can be used either independently or in proper combination.

The resin substrate used in the present invention is not subjected to the aforementioned description. When it is used in a flat panel display (e.g., OLED, liquid crystal, FED, SED and PDP) or as an electronic material, the glass transition temperature is preferably 150° C. or more. Polyether sulfone, polycarbonate, norbornane based resin, transparent polyimide disclosed in the Unexamined Japanese Patent Application Publication No. 2003-192787, copolymer polycarbonate disclosed in the Unexamined Japanese Patent Application Publication No. 2001-139676, and Unexamined Japanese Patent Application Publication No. 2002-179784, and a transparent film disclosed in the Unexamined Japanese Patent Application Publication No. 2004-196841 are preferably used. Among others, such commercially available products as Zeonoa (by Nippon Zeon Co., Ltd.), Zeonoa (by Nippon Zeon Co., Ltd.) of norbornane resin film, ARTON (by J.S.R.), Pure Ace (by Teijin Chemical) of polycarbonate film, and Sumilite (by Sumitomo Bakelite) of polyether sulfone film are preferably utilized. The thickness of the film-like substance is preferably 10 through 1000 μm, more preferably 40 through 500 μm.

The moisture permeation of the gas barrier resin substrate in the present invention measured according to the JIS K7129 B is less than 0.1 g/m²/day, and the oxygen permeation measured according to the JIS K7126 B is preferably 0.1 cc/m²/day/atm or less, when the substrate is used for the application requiring a high-quality gas barrier function in the organic EL display and high definition color liquid crystal display.

The OLED on the substrate can be laminated and sealed onto the gas barrier resin substrate of the present invention through an epoxy adhesive or the like. The epoxy adhesive commercially sold by THREEBOND Inc. and Nagasechem Tex Inc. can be used as an OLED sealing material.

The OLED with its gas barrier function enhanced by the aforementioned gas barrier thin film laminate or gas barrier resin substrate will be described using typical examples, without the present invention being restricted thereto.

The electron and positive hole injected through anode and cathode respectively are re-bonded together on the light emitting layer, and an exciton (ethoxy) is generated. Then light (fluorescent or phosphorescent light) is emitted when the ethoxy is deactivated. The organic EL device emits light using this light. This structure is disclosed in C. W. Tang, S. A. Van Slyke., Applied Physics Letters, Vol. 51, P. 913 (1987), Specification of U.S. Pat. No. 3,093,796, and Unexamined Japanese Patent Application Publication No. S63-264692. The organic electroluminescence device based on phosphorescent light emission from the excited triplet using a phosphorescent dorpant and host compound is reported in the M. A. Baldo et. al., nature, Vol. 395, P. 151-154 (1998). The structure is descried in the Unexamined Japanese Patent Application Publication No. 3-255190.

The organic EL device is structured in such a way that an electrode made up of at least an anode and cathode, and an organic compound layer such as a positive hole transport layer, light emitting layer, positive hole inhibiting layer, electron transport layer sandwiched between the aforementioned electrodes are sequentially formed on a substrate. Thus, in one form of configuration, the OLED wherein the gas barrier function of the present invention is enhanced is arranged in such a way that, when the substrate of low moisture permeability such as glass is used as the aforementioned substrate, the aforementioned organic compound layer including the electrode and the light emitting layer formed on the aforementioned substrate is covered by the gas barrier thin film laminate of the aforementioned the present invention. This arrangement allows the organic EL device to be sealed. FIG. 6 is a cross sectional view showing an example of the sealed form of an organic EL device.

In FIG. 6, 2 denotes a glass substrate. An anode 4, organic compound layer 5 and cathode 6 are formed sequentially on the aforementioned glass substrate. The gas barrier thin film laminate 7 of the present invention is formed, for example, by the atmospheric pressure plasma method in such a way as to cover the organic compound layer and cathode. The gas barrier thin film laminate has a structure of stress relaxation film/inorganic film/stress relaxation film/inorganic film/stress relaxation film, for example.

In another embodiment, electrodes and organic compound layers including a light emitting layer formed on a substrate such as the aforementioned low moisture permeability glass is covered by the gas barrier resin substrate of the present invention to form an organic EL device, wherein the gas barrier resin substrate is adhered with the substrate such as glass on which the organic EL device is formed to seal the organic EL device. As described above, epoxy adhesive can be used for this lamination. The OLED sealing material is exemplified by the epoxy adhesive commercially sold by THREEBOND Inc. and Nagasechem Tex Inc. FIG. 7 is a cross sectional view showing an example of an organic EL device formed on the glass substrate and sealed by gas barrier resin substrate of the present invention. In FIG. 2, 2 denotes a glass substrate. The anode 4, organic compound layer 5 and cathode 6 are sequentially formed on the aforementioned glass substrate, and the gas barrier resin substrate made up of the gas barrier thin film laminate 3 and resin substrate 1 of the present invention is arranged so as to cover them. The substrate is bonded with the glass substrate 2 and sealed by the adhesive 9 around each organic EL layer.

In still another embodiment, an electrode made up of at least an anode and cathode, and an organic compound layer including the light emitting layer sandwiched between the aforementioned electrodes are formed on the gas barrier resin substrate of the present invention. After that, the gas barrier thin film laminate of the present invention is arranged so as to cover the electrode and organic compound layer whereby the organic EL device is sealed. This embodiment is shown in FIG. 8. In FIG. 8, the anode 4, organic compound layer 5 and cathode 6 sequentially arranged on the gas barrier resin substrate of the present invention formed on the resin substrate 1 with the gas barrier thin film laminate 3 is sealed by the gas barrier thin film laminate 3 of the present invention.

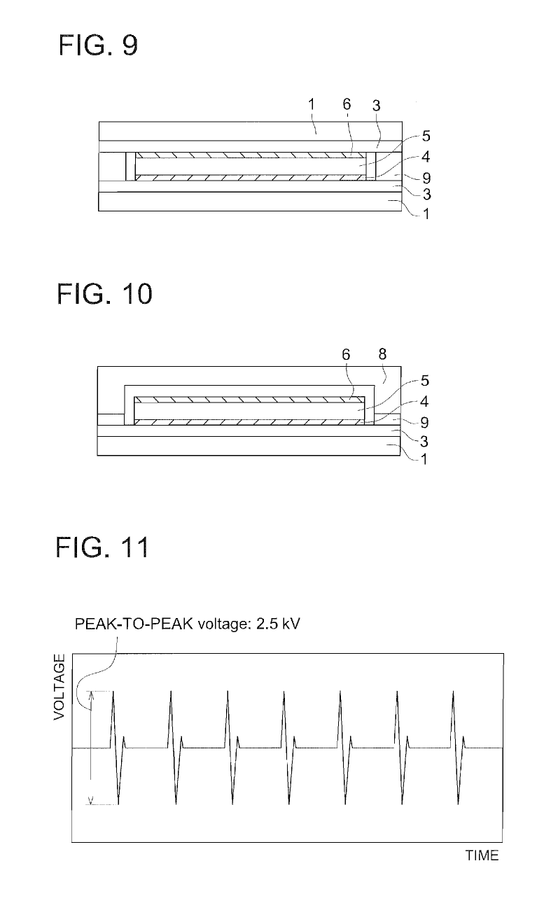

In a further embodiment, in an organic EL device wherein an electrode made up of at least an anode and cathode, and an organic compound layer including the light emitting layer sandwiched between the aforementioned electrodes are formed on the gas barrier resin substrate of the present invention, the gas barrier resin substrate of the present invention is further arranged and bonded so as to cover the aforementioned electrode and organic compound layer, and the organic EL device is sealed by two gas barrier resin substrates. This is illustrated in FIG. 9. In FIG. 9, the gas barrier thin film laminate 3 of the present invention and the gas barrier resin substrate made up of the resin substrate 1 containing the same are arranged on the anode 4, organic compound layer 5 and cathode 6 sequentially formed on the resin substrate 1 constituting the gas barrier thin film laminate 3 so as to cover them. The gas barrier resin substrates of the present invention are bonded and sealed with each other by the adhesive 9 around the layers of the organic EL.

It is also possible to make such arrangements that the electrode and organic compound layer are covered with the substrate made of a material having a low moisture permeability such as glass, and are bonded by an adhesive, as described above. This is illustrated in FIG. 10.

In FIG. 10, the anode 4, organic compound layer 5 and cathode 6 are sequentially formed on the gas barrier resin substrate made of the gas barrier thin film laminate 3 and resin substrate 1. A drum member (cover) 8 made of glass or the like having a low moisture permeability is placed thereon so as to cover them, and is bonded and sealed by the adhesive 9 around the layers of the organic EL. The schematic diagram does not show the lead wire to be led from the electrode to the outside.

### EXAMPLES

The following describes the examples of the present invention, however, the present invention is not limited thereto.

### Example 1

### Manufacture of Electrode

Using the atmospheric pressure plasma discharge processing apparatus of FIG. 2, a roll electrode covered with a dielectric and a plurality of rectangular electrodes also covered with a dielectric were manufactured as a set according to the following procedure:

The roll electrode to be made into a first electrode was manufactured in such a way that a jacket roll metallic base material of titanium alloy T64 having a means to keep a predetermined temperature was covered with an alumina thermal spray-coated film of higher density and closer adhesion according to the atmospheric plasma method to have a roll diameter of 1000 mm.

The dielectric surface provided with pore sealing coating was ground to a surface roughness of Rmax 5 μm. The final dielectric void ratio (void ratio of sufficient penetrability) was almost 0% by volume, the percentage of SiOx content in the dielectric layer at this time was 75 mol %, the final dielectric film thickness was is 1 mm, and dielectric relative dielectric constant was 10. Further, the difference in the linear thermal coefficient of expansion between the conductive metallic base material and dielectric was 1.7×10⁻⁶, and the heat-resistant temperature was 260° C.

The rectangular electrode as the second electrode was formed as a group of rectangular fixed opposing electrodes wherein the hollow rectangular titanium alloy T64 was coated with the dielectric under the same conditions as described above. The dielectric of the rectangular electrode of the aforementioned roll type was finished to have almost the same physical properties as those of the dielectric of the first electrode, with respect to the dielectric surface roughness Rmax, the percentage of SiOx content in the dielectric layer, dielectric film thickness, relative dielectric constant, the difference in the linear thermal coefficient of expansion between the metallic base material and dielectric, and the electrode heat-resistant temperature.

Twenty-five rectangular electrodes were arranged around the roll rotating electrode wherein the space between opposing electrodes was 1 mm. The overall electric discharge area of the rectangular fixed electrode group was 150 cm (length in lateral direction)×4 cm (length in the direction of conveyance)×25 (number of electrodes)=15000 cm². In this case, an appropriate filter was installed.

### Manufacture of Sample 1

A hard coated layer was formed on the resin substrate (polyester naphthalate 125 μm thick by Teijin DuPont Film) under the following conditions. After that, using the atmospheric pressure plasma discharge processing apparatus of FIG. 2 employing the electrode manufactured in the aforementioned procedure, the roll rotating electrode was driven and rotated, and thin film was formed sequentially under the following conditions. A gas barrier thin film laminate (stress relaxation film; 200 nm thick, inorganic film; 50 nm thick) having a structure of resin substrate/stress relaxation film/inorganic film/stress relaxation film was formed, whereby a sample 1 was produced.

(Formation of Hard Coated Layer)

The following hard coated layer composition was coated on the film constituting the aforementioned antistatic layer so that dry film thickness was 6.5 μm, and was dried at 80° C. for five minutes. Then it was exposed to the light of a 80 W/cm high pressure mercury lamp from a distance of 12 cm for four seconds, whereby a hard coated film including a hard coated layer was produced. The hard coated layer had a refractive index of 1.50.

<Hard Coated Layer Composition>

Dipentaerythritol hexaacrylate monomer: 60 parts by mass

Dipentaerythritol hexaacrylate dimer: 20 parts by mass

Dipentaerythritol hexaacrylate having three or more monomers: 20 parts by mass

Diethoxy benzophenone (photo-polymerization initiator): 2 parts by mass

Methyl ethyl ketone: 50 parts by mass

Ethyl acetate: 50 parts by mass

Isopropyl alcohol: 50 parts by mass

These compositions were stirred and dissolved.

(Manufacture of Stress Relaxation Film)

A stress relaxation film was manufactured under the following conditions on the hard coated film obtained above.

<Stress Relaxation Film Gas Mixture Composition>

Electrical discharge gas: nitrogen gas: 94.4% by volume

Thin film forming gas: tetraethoxy silane: 0.1% by volume

Thin film forming gas: methyl methacrylate: 0.5% by volume

Additive gas: methane gas: 5.0% by volume

<Stress Relaxation Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 5 W/cm² (Voltage Vp was 1 kV in this case)

Electrode temperature: 90° C.

(Manufacture of Inorganic Film (Silicon Oxide Film))

An inorganic film (silicon oxide film) was manufactured under the following conditions:

<Inorganic Film Gas Mixture Composition>

Electrical discharge gas: nitrogen gas 94.9% by volume

Thin film forming gas: tetraethoxy silane: 0.1% by volume

Additive gas: oxygen gas: 5.0% by volume

<Inorganic Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 10 W/cm (Voltage Vp was 2 kV in this case)

Electrode temperature: 90° C.

### Manufacture of Sample 2

### Comparative Example

The sample 2 was manufactured in the same way as the aforementioned sample 1, except that the stress relaxation film forming conditions were modified as follows:

<Stress Relaxation Film Forming Conditions>

Power source on the first electrode side: Not used

Power source on the second electrode side: A5

Frequency: 8 kHz (pulse electric field of FIG. 11 applied)

output power density: 1 W/cm² (Voltage Vp was 5 kV in this case)

Electrode temperature: 90° C.

### Manufacture of Sample 3

The sample 3 was manufactured in the same way as the aforementioned sample 1, except that gas mixture conditions of the stress relaxation film were modified as follows:

<Stress Relaxation Film Gas Mixture Composition>

Electrical discharge gas: nitrogen gas: 98.6% by volume

Thin film forming gas: tetraethoxy silane: 0.19% by volume

Thin film forming gas: 3-ethyl-3-hydroxymethyl oxetane: 0.3% by volume

Additive gas: hydrogen gas: 1.0% by volume

### Manufacture of Sample 4

### Comparative Example

The sample 4 was manufactured in the same way as the aforementioned sample 3, except that the stress relaxation film forming conditions were modified as follows:

<Stress Relaxation Film Gas Mixture Composition>

Electrical discharge gas: helium gas: 98.6% by volume

Thin film forming gas: tetraethoxy silane: 0.1% by volume

Thin film forming gas: 3-ethyl-3-hydroxymethyl oxetane: 0.3% by volume

Additive gas: hydrogen gas: 1.0% by volume

<Stress Relaxation Film Forming Conditions>

Power source on the first electrode side: Not used

Power source on the second electrode side: A1

Frequency: 35 kHz

output power density: 0.5 W/cm² (Voltage Vp was 1 kV in this case)

Electrode temperature: 90° C.

### Manufacture of Sample 5

The sample 5 was manufactured in the same way as the aforementioned sample 1, except that gas mixture conditions of the stress relaxation film were modified as follows:

<Stress Relaxation Film Gas Mixture Composition>

Electrical discharge gas: nitrogen gas: 98.6% by volume

Thin film forming gas: 3-methacryloxypropyltrimethoxy silane: 0.1% by volume

Thin film forming gas: 1,6-hexane diol diglycidylether: 0.3% by volume

Additive gas: ethanol: 1.0% by volume

### Manufacture of Sample 6

### Comparative Example

The sample 6 was manufactured in the same way as the aforementioned sample 5, except that the stress relaxation film manufacturing conditions were modified as follows:

<Stress Relaxation Film Gas Mixture Composition>

Electrical discharge gas: helium gas: 98.6% by volume

Thin film forming gas: 3-methacryloxypropyltrimethoxy silane: 0.1% by volume

Thin film forming gas: 1,6-hexane diol diglycidylether: 0.3% by volume

Additive gas: ethanol: 1.0% by volume

<Stress Relaxation Film Forming Conditions>

Power source on the first electrode side: Not used

Power source on the second electrode side: B3

Frequency: 13.56 MHz

output power density: 5 W/cm² (Voltage Vp was 1 kV in this case)

Electrode temperature: 90° C.

<<Evaluation of Characteristic Value of Each Sample>>

[Evaluation 1: Evaluation of Unprocessed Sample]

The samples 1 through 6 as the gas barrier resin substrates manufactured according to the aforementioned procedure were evaluated as follows:

(Measurement of Moisture Permeation)

Moisture permeation was measured according to the method specified in the JIS K 7129B (moisture permeation measuring apparatus PERMATRAN-W 3/33 MG module by MOCON).

(Measurement of Oxygen Permeation)

Oxygen permeation was measured according to the method specified in the JIS K 7126B (oxygen permeation measuring apparatus OX-TRAN 2/21 MH module by MOCON).

[Evaluation 2: Evaluation of Samples after being Bent]

The gas barrier resin substrate manufactured according to the aforementioned procedure was wound on a metal rod having a diameter of 100 mmφ so that the surfaces of each constituent layer would be located outside, and was released after 5 seconds. After repeating this operation ten times, moisture permeation and oxygen permeation were measured according to the method described in Evaluation 1.

Table 1 shows the results of the aforementioned procedures:

TABLE 1

| | Not treated | | After bending | | |
|---|---|---|---|---|---|
| | Moisture | Oxygen | moisture | Oxygen | |
| Sample | permeation | permeation | permeation | permeation | |
| No. | g/m²/day | cc/m²/day/atm | g/m²/day | cc/m²/day/atm | |
| 1 | <0.1 | <0.1 | <0.1 | <0.1 | Present |
| | | | | | invention |
| 2 | 0.43 | 0.54 | 0.76 | 0.83 | Comparative |
| | | | | | example |
| 3 | <0.1 | <0.1 | <0.1 | <0.1 | Present |
| | | | | | invention |
| 4 | 0.35 | 0.63 | 0.88 | 1.2 | Comparative |
| | | | | | example |
| 5 | <0.1 | <0.1 | <0.1 | <0.1 | Present |
| | | | | | invention |
| 6 | 0.12 | 0.17 | 0.45 | 0.55 | Comparative |
| | | | | | example |

As is clear from the result shown in Table 1, the gas barrier thin film laminate of the present invention exhibited excellent performances with regard to moisture shielding effect, oxygen shielding effect and resistance to bending as compared to the Comparative Example.

### Example 2

### Manufacture of Sample 7

Sample 7 was manufactured in the same procedure as that of the aforementioned sample 1, except that the layer was designed in the structure of resin substrate/stress relaxation film/inorganic film/stress relaxation film/inorganic film/stress relaxation film and the stress relaxation film forming conditions were modified as follows: The stress relaxation film was 200 nm thick, and inorganic film was 50 nm thick.

<Stress Relaxation Film Gas Mixture Composition>

Electrical discharge gas: nitrogen gas: 94.4% by volume

Thin film forming gas: hexamethyl disiloxane: 0.1% by volume

Thin film forming gas: neopentyl glycolate diacrylate: 0.5% by volume

Additive gas: methane gas: 5.0% by volume

<Stress Relaxation Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 5 W/cm² (Voltage Vp was 1 kV in this case)

Electrode temperature: 90° C.

### Manufacture of Sample 8

### Comparative Example 9

Sample 8 was manufactured in the same procedure as that of the aforementioned sample 7, except that stress relaxation film forming conditions were modified as follows:

<Stress Relaxation Film Forming Conditions>

Power source on the first electrode side: Not used

Power source on the second electrode side: A5

Frequency: 8 kHz (Pulse electric field of FIG. 11 was applied)

output power density: 1 W/cm² (Voltage Vp was 5 kV in this case)

Electrode temperature: 90° C.

<<Evaluation of Characteristics of Each Sample>>

Substrates equipped with as barrier thin film laminate of samples 7 and 8 were used as organic EL display substrates. A transparent electrode constituting an anode electrode, a positive hole transport layer for transporting positive hole, a light emitting layer, an electron injection layer, and rear surface electrode as a cathode were laminated thereon. The OLED sealed by the glass bottle bonded with the epoxy based sealing material was formed on each of these layers (structure shown in FIG. 10). The sample was left to stand at 60° C. with a relative humidity of 90% RH for 1000 hours. After that, a photograph enlarged 50 times was taken to evaluate the occurrence of a dark spot. It has been revealed that no dark spot was observed in the sample 7 of the present invention, but many dark spots were found in the sample 8 as a Comparative Example. As described above, the gas barrier thin film laminate of the present invention exhibited excellent performances in moisture shielding effect and oxygen shielding effect even after having been left to stand for a long time at high temperature and high humidity, as compared with the Comparative Example.

Instead of the glass bottle, the gas barrier resin substrate manufactured under the same conditions as sample 7 was used to seal the OLED (structure shown in FIG. 9 wherein epoxy adhesive 3124C by THREEBOND was used as an adhesive) manufactured using the sample 7. Similarly, no dark spot was observed.

### Example 3

### Manufacture of Sample 9

Thin films were formed sequentially on the OLED laminated with 0.5 mm thick alkali-free glass (1737 by Corning), a transparent electrode constituting the anode electrode, a positive hole transport layer for transporting a positive hole, a light emitting layer, an electron injection layer, and a rear surface electrode as a cathode, under the following manufacturing conditions using an atmospheric pressure plasma discharge processing apparatus of FIG. 1. A gas barrier thin film laminate (stress relaxation film; 200 nm thick, inorganic film; 50 nm thick) having a structure of OLED/stress relaxation film/inorganic film/stress relaxation film/inorganic film/stress relaxation film was formed, whereby the sample 9 was produced.

Stress relaxation film gas mixture composition

Electrical discharge gas: nitrogen gas: 94.4% by volume

Thin film forming gas: tetraethoxy silane: 0.1% by volume

Thin film forming gas: methyl methacrylate: 0.5% by volume

Additive gas: methane gas: 5.0% by volume

<Stress Relaxation Film Forming Conditions>

Power source on the first electrode side: A5

Frequency: 100 kHz

output power density: 10 W/cm² (Voltage Vp was 7 kV in this case)

Electrode temperature: 90° C.

Power source on the second electrode side: B3

Frequency: 13.56 MHz

output power density: 5 W/cm² (Voltage Vp was 1 kV in this case)

Electrode temperature: 90° C.

(Manufacture of Inorganic Film (Silicon Oxide Film))

An inorganic film (silicon oxide film) was formed under the following conditions:

<Inorganic Film Gas Mixture Composition>

Electrical discharge gas: nitrogen gas: 94.9% by volume

Thin film forming gas: hexamethyl disiloxane: 0.1% by volume

(Mixed with Nitrogen Gas and Vaporized by a Vaporizer of Lintec)

Additive gas: oxygen gas: 5.0% by volume

<Inorganic Film Forming Conditions>

Power source on the first electrode side: A5

Frequency: 100 kHz

output power density: 10 W/cm² (Voltage Vp was 7 kV in this case)

Electrode temperature: 90° C.

Power source on the second electrode side: B3

Frequency: 13.56 MHz

output power density: 10 W/cm² (Voltage Vp was 2 kV in this case)

Electrode temperature: 90° C.

### Manufacture of Sample 10

### Comparative Example

Sample 10 was manufactured in the same procedure as that of the aforementioned sample 9, except that stress relaxation film forming conditions were modified as follows:

<Stress Relaxation Film Forming Conditions>

Power source on the first electrode side: Not used

Power source on the second electrode side: A5

Frequency: 8 kHz (Pulse electric field of FIG. 11 was applied)

output power density: 1 W/cm² (Voltage Vp was 5 kV in this case)

Electrode temperature: 90° C.

The gas barrier thin film laminates of samples 9 and 10 were laminated on the OLED as sealing films to seal each layer of the organic EL (having a structure of FIG. 6).

<<Evaluation of Characteristics of Each Sample>>

Each sample was left to stand at 60° C. with a relative humidity of 90% RH for 1000 hours. After that, a photograph enlarged 50 times was taken to evaluate the occurrence of a dark spot. It has been revealed that no dark spot was observed in the sample 9 of the present invention, but many dark spots were found in the sample 10 as a Comparative Example. As described above, the gas barrier thin film laminate of the present invention exhibited excellent performances in moisture shielding effect and oxygen shielding effect, as compared with the Comparative Example.

### Example 4

### Manufacture of Electrode

In the atmospheric pressure plasma discharge processing apparatus of FIG. 2, a roll electrode coated with dielectric and a plurality of rectangular electrodes also coated with dielectric were manufactured as follows.

The roll electrode to be made into a first electrode was manufactured in such a way that a jacket roll metallic base material of titanium alloy T64 having a means for keeping a predetermined temperature was covered with an alumina thermal spray-coated film of higher density and closer adhesion according to the atmospheric plasma method and that the roll had a diameter of 1000 mmφ.

The dielectric surface provided with pore sealing coating was ground to a surface roughness of Rmax 5 μm. The final dielectric void ratio (void ratio of sufficient penetrability) was almost 0% by volume, the percentage of SiOx content in the dielectric layer at this time was 75 mol %, the final dielectric film thickness was is 1 mm, and dielectric relative dielectric constant was 10. Further, the difference in the linear thermal coefficient of expansion between the conductive metallic base material and dielectric was 1.7×10⁻⁶, and the heat-resistant temperature was 260° C.

The rectangular electrode as the second electrode was formed as a group of rectangular fixed opposing electrodes wherein the hollow rectangular titanium alloy T64 was coated with the dielectric under the same conditions as described above. The dielectric of the rectangular electrode of the aforementioned roll type was finished to have almost the same physical properties as those of the dielectric of the first electrode, in regard to the dielectric surface roughness Rmax, the percentage of SiOx content in the dielectric layer, dielectric film thickness, relative dielectric constant, the difference in the linear thermal coefficient of expansion between the metallic base material and dielectric, and the electrode heat-resistant temperature.

Twenty-five rectangular electrodes were arranged around the roll rotating electrode wherein the space between opposing electrodes was 1 mm. The overall electric discharge area of the rectangular fixed electrode group was 150 cm (length in lateral direction)×4 cm (length in the direction of conveyance)×25 (number of electrodes)=15000 cm². In this case, an appropriate filter was installed.

### Manufacture of Sample 11

A hard coated layer was formed on the resin substrate (polyether sulfone film 200 μm thick by Sumitomo Bakelite) using the atmospheric pressure plasma discharge processing apparatus of FIG. 2 employing the electrode manufactured in the aforementioned procedure. The roll rotating electrode was driven and rotated, and thin film was formed sequentially under the following conditions. A gas barrier thin film laminate (stress relaxation film; 200 nm thick, adhesive film; 5 nm, and inorganic film; 50 nm thick) having a structure of resin substrate/stress relaxation film/adhesive film/inorganic film/adhesive film/stress relaxation film was formed, whereby a sample 11 was produced.

(Formation of Stress Relaxation Film)

A stress relaxation film was formed under the following conditions:

<Stress Relaxation Film Gas Mixture Composition>

Electrical discharge gas: nitrogen gas: 94.5% by volume

Thin film forming gas: methyl methacrylate: 0.5% by volume

(Mixed with Nitrogen Gas and Vaporized by a Vaporizer of Lintec)

Additive gas: methane gas: 5.0% by volume

<Stress Relaxation Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 5 W/cm² (Voltage Vp was 1 kV in this case)

Electrode temperature: 90° C.

(Formation of Inorganic Film (Silicon Oxide Film))

The inorganic film (silicon oxide film)) was formed under the following conditions:

<Inorganic Film Gas Mixture Composition>

Electrical discharge gas: nitrogen gas: 94.9% by volume

Thin film forming gas: tetraethoxy silane: 0.1% by volume

(Mixed with Nitrogen Gas and Vaporized by a Vaporizer of Lintec)

Additive gas: oxygen gas: 5.0% by volume

<Inorganic Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 10 W/cm² (Voltage Vp was 2 kV in this case)

Electrode temperature: 90° C.

(Formation of Adhesive Film)

The adhesive film was formed under the following conditions:

<Adhesive Film Gas Mixture Composition>

Electrical discharge gas: nitrogen gas: 94.9% by volume

Thin film forming gas: tetraethoxy silane: 0.1% by volume

(Mixed with Nitrogen Gas and Vaporized by a Vaporizer of Lintec)

Thin film forming gas: methyl methacrylate: 0.5% by volume

(Mixed with Nitrogen Gas and Vaporized by a Vaporizer of Lintec)

Additive gas: methane gas: 5.0% by volume

<Adhesive Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 5 W/cm² (Voltage Vp was 1 kV in this case)

Electrode temperature: 90° C.

### Manufacture of Sample 12

### Comparative Example

Sample 12 was manufactured in the same procedure as that of the aforementioned sample 11, except that stress relaxation film forming conditions were modified as follows:

<Stress Relaxation Film Forming Conditions>

Power source on the first electrode side: Not used

Power source on the second electrode side: A5

Frequency: 8 kHz (Pulse electric field of FIG. 5 was applied)

output power density: 1 W/cm² (Voltage Vp was 5 kV in this case)

Electrode temperature: 90° C.

### Manufacture of Sample 13

Sample 13 was manufactured in the same procedure as that of the aforementioned sample 11, except that stress relaxation film gas mixture conditions were modified as follows:

<Stress Relaxation Film Gas Mixture Composition>

Electrical discharge gas: nitrogen gas: 99.7% by volume

Thin film forming gas: 3-ethyl-3-hydroxymethyl oxetane: 0.3% by volume

(Mixed with Nitrogen Gas and Vaporized by a Vaporizer of Lintec)

### Manufacture of Sample 14

### Comparative Example

Sample 14 was manufactured in the same procedure as that of the aforementioned sample 13, except that stress relaxation film forming conditions were modified as follows:

<Stress Relaxation Film Gas Mixture Composition>

Electrical discharge gas: helium gas: 99.7% by volume

Thin film forming gas: 3-ethyl-3-hydroxymethyl oxetane: 0.3% by volume

(Mixed with Nitrogen Gas and Vaporized by a Vaporizer of Lintec)

<Stress Relaxation Film Forming Conditions>

Power source on the first electrode side: Not used

Power source on the second electrode side: A1

Frequency: 3 kHz

output power density: 0.5 W/cm² (Voltage Vp was 1 kV in this case)

Electrode temperature: 90° C.

### Manufacture of Sample 15

Sample 15 was manufactured in the same procedure as that of the aforementioned sample 11, except that stress relaxation film gas mixture conditions were modified as follows:

<Stress Relaxation Film Gas Mixture Composition>

Electrical discharge gas: nitrogen gas: 98.7% by volume

Thin film forming gas: 1,6-hexane diol diglycidylether: 0.3% by volume

(Mixed with Nitrogen Gas and Vaporized by a Vaporizer of Lintec)

Additive gas: ethanol: 1.0% by volume

### Manufacture of Sample 16

### Comparative Example

Sample 16 was manufactured in the same procedure as that of the aforementioned sample 15, except that stress relaxation film forming conditions were modified as follows:

<Stress Relaxation Film Gas Mixture Composition>

Electrical discharge gas: helium gas: 98.7% by volume

Thin film forming gas: 1,6-hexane diol diglycidylether: 0.3% by volume

(Mixed with Nitrogen Gas and Vaporized by a Vaporizer of Lintec)

Additive gas: methane gas: 1.0% by volume

<Stress Relaxation Film Forming Conditions>

Power source on the first electrode side: Not used

Power source on the second electrode side: B3

Frequency: 13.56 MHz

output power density: 5 W/cm² (Voltage Vp was 1 kV in this case)

Electrode temperature: 90° C.

<Evaluation of Characteristic Value of Each Sample>

[Evaluation 1: Evaluation of Unprocessed Sample]

The gas barrier resin substrates manufactured according to the aforementioned procedure were evaluated as follows:

(Measurement of Moisture Permeation)

Moisture permeation was measured according to the method described in Example 1.

(Measurement of Oxygen Permeation)

Oxygen permeation was measured according to the method described in Example 1.

[Evaluation 2: Evaluation of Samples after being Bent]

The samples after being bent were evaluated in the method as that in Example 1.

Table 2 shows the results obtained from the aforementioned procedure.

TABLE 2

| | Not treated | | After bending | | |
|---|---|---|---|---|---|
| | Moisture | Oxygen | moisture | Oxygen | |
| Sample | permeation | permeation | permeation | permeation | |
| No. | g/m²/day | cc/m²/day/atm | g/m²/day | cc/m²/day/atm | |
| 1 | <0.1 | <0.1 | <0.1 | <0.1 | Present |
| | | | | | invention |
| 2 | 0.19 | 0.58 | 0.38 | 0.97 | Comparative |
| | | | | | example |
| 3 | <0.1 | <0.1 | <0.1 | <0.1 | Present |
| | | | | | invention |
| 4 | 0.28 | 0.64 | 0.92 | 2.4 | Comparative |
| | | | | | example |
| 5 | <0.1 | <0.1 | <0.1 | <0.1 | Present |
| | | | | | invention |
| 6 | <0.1 | <0.1 | 0.32 | 1.2 | Comparative |
| | | | | | example |

As is clear from the result shown in Table 2, the gas barrier thin film laminate of the present invention exhibited excellent performances with regard to moisture shielding effect, oxygen shielding effect and resistance to bending as compared to the Comparative Example.

### Example 5

### Manufacture of Sample 17

Sample 17 was manufactured in the same procedure as that of the aforementioned sample 11 described in Example 4, except that the resin substrate was a polycarbonate film (200 μm thick by Teijin DuPont Film), the layer was designed in the structure of resin substrate/stress relaxation film/adhesive film/inorganic film/adhesive film/stress relaxation film/adhesive film/inorganic film/adhesive film/stress relaxation film, and the stress relaxation film forming conditions were modified as follows: In this case, the stress relaxation film was 200 nm thick, the adhesive film was 5 nm thick, and the inorganic film was 50 nm thick.

<Stress Relaxation Film Gas Mixture Composition>

Electrical discharge gas: nitrogen gas: 94.7% by volume

Thin film forming gas: neopentyl glycolate diacrylate: 0.5% by volume

(Mixed with Nitrogen Gas and Vaporized by a Vaporizer of Lintec)

Additive gas: methane gas: 5.0% by volume

<Stress Relaxation Film Forming Conditions>

Power source on the first electrode side: A5

Frequency: 100 kHz

output power density: 10 W/cm² (Voltage Vp was 7 kV in this case)

Electrode temperature: 120° C.

Power source on the second electrode side: B3

Frequency: 13.56 MHz

output power density: 5 W/cm² (Voltage Vp was 1 kV in this case)

Electrode temperature: 90° C.

### Manufacture of Sample 18

### Comparative Example

Sample 18 was manufactured in the same procedure as that of the aforementioned sample 17, except that stress relaxation film forming conditions were modified as follows:

<Stress Relaxation Film Forming Conditions>

Power source on the first electrode side: Not used

Power source on the second electrode side: A5

Frequency: 8 kHz (Pulse electric field of FIG. 5 was applied)

output power density: 1 W/cm² (Voltage Vp was 5 kV in this case)

Electrode temperature: 90° C.

<<Evaluation of Characteristics of Each Sample>>

Substrates equipped with as barrier thin film laminate of samples 17 and 18 were used as organic EL display substrates. A transparent electrode constituting an anode electrode, a positive hole transport layer for transporting positive hole, a light emitting layer, an electron injection layer, and rear surface electrode as a cathode were laminated thereon. The OLED sealed by the glass bottle bonded with the epoxy based sealing material was formed on each of these layers. The sample was left to stand at 80° C. with a relative humidity of 90% RH for 300 hours. After that, a photograph enlarged 50 times was taken to evaluate the occurrence of a dark spot. It has been revealed that no dark spot was observed in the sample 17 of the present invention, but many dark spots were found in the sample 18 as a Comparative Example. As described above, the gas barrier thin film laminate of the present invention exhibited excellent performances in moisture shielding effect and oxygen shielding effect even after having been left to stand for a long time at high temperature and high humidity, as compared with the Comparative Example.

Instead of the glass bottle, the gas barrier resin substrate manufactured under the same conditions as sample 17 was used to seal the OLED manufactured using the sample 17. Similarly, no dark spot was observed.

### Example 6

### Manufacture of Sample 19

Thin films were formed sequentially on the OLED laminated with 0.5 mm thick alkali-free glass (1737 by Corning), a transparent electrode constituting the anode electrode, a positive hole transport layer for transporting a positive hole, a light emitting layer, an electron injection layer, and a rear surface electrode as a cathode, under the following manufacturing conditions using an atmospheric pressure plasma discharge processing apparatus of FIG. 1. A gas barrier thin film laminate (stress relaxation film; 200 nm thick, adhesive film; 2 nm thick, inorganic film; 50 nm thick) having a structure of OLED/stress relaxation film/adhesive film/inorganic film/adhesive film/stress relaxation film/adhesive film/inorganic film/adhesive film/stress relaxation film was formed, whereby the sample 19 was produced.

<Stress Relaxation Film Gas Mixture Composition>

Electrical discharge gas: nitrogen gas: 94.7% by volume

Thin film forming gas: neopentyl glycolate diacrylate: 0.5% by volume

(Mixed with Nitrogen Gas and Vaporized by a Vaporizer of Lintec)

Additive gas: methane gas: 5.0% by volume

<Stress Relaxation Film Forming Conditions>

Power source on the first electrode side: A5

Frequency: 100 kHz

output power density: 10 W/cm² (Voltage Vp was 7 kV in this case)

Electrode temperature: 90° C.

Power source on the second electrode side: B3

Frequency: 13.56 MHz

output power density: 5 W/cm² (Voltage Vp was 1 kV in this case)

Electrode temperature: 90° C.

(Formation of Inorganic Film (Silicon Oxide Film))

The inorganic film (silicon oxide film)) was formed under the following conditions:

<Inorganic Film Gas Mixture Composition>

Electrical discharge gas: nitrogen gas: 94.9% by volume

Thin film forming gas: hexamethyl disiloxane: 0.1% by volume

(Mixed with Nitrogen Gas and Vaporized by a Vaporizer of Lintec)

Additive gas: oxygen gas: 5.0% by volume

<Inorganic Film Forming Conditions>

Power source on the first electrode side: A5

Frequency: 100 kHz

output power density: 10 W/cm² (Voltage Vp was 7 kV in this case)

Electrode temperature: 90° C.

Power source on the second electrode side: B3

Frequency: 13.56 MHz

output power density: 10 W/cm² (Voltage Vp was 2 kV in this case)

Electrode temperature: 90° C.

(Formation of Adhesive Film)

The adhesive film was formed under the following conditions:

<Adhesive Film Gas Mixture Composition>

Electrical discharge gas: nitrogen gas: 99.5% by volume

Thin film forming gas: 3-glusidexypropyl triethoxy silane: 0.5% by volume

(Mixed with Nitrogen Gas and Vaporized by a Vaporizer of Lintec)

<Adhesive Film Forming Conditions>

Power source on the first electrode side: A5

Frequency: 100 kHz

output power density: 10 W/cm² (Voltage Vp was 7 kV in this case)

Electrode temperature: 90° C.

Power source on the second electrode side: B3

Frequency: 13.56 MHz

output power density: 5 W/cm² (Voltage Vp was 1 kV in this case)

Electrode temperature: 90° C.

### Manufacture of Sample 20

### Comparative Example

Sample 20 was manufactured in the same procedure as that of the aforementioned sample 19, except that stress relaxation film forming conditions were modified as follows:

<Stress Relaxation Film Forming Conditions>

Power source on the first electrode side: Not used

Power source on the second electrode side: A5

Frequency: 8 kHz (Pulse electric field of FIG. 5 was applied)

output power density: 1 W/cm² (Voltage Vp was 5 kV in this case)

Electrode temperature: 90° C.

<<Evaluation of Characteristics of Each Sample>>

The gas barrier thin film laminates of samples 19 and 20 were laminated on the OLED as sealing films and were left to stand at 80° C. with a relative humidity of 90% RH for 300 hours. After that, a photograph enlarged 50 times was taken to evaluate the occurrence of a dark spot. It has been revealed that no dark spot was observed in the sample 19 of the present invention, but many dark spots were found in the sample 20 as a Comparative Example. As described above, the gas barrier thin film laminate of the present invention exhibited excellent performances in moisture shielding effect and oxygen shielding effect.

### Example 7

### Manufacture of Sample 21

A hard coated layer used to produce the sample 1 described in Example 1 was formed on the resin substrate (polyester naphthalate 125 μm thick by Teijin DuPont Film). After that, the stress relaxation film/inorganic film/stress relaxation film used to produce the sample 7 described 2 was similarly formed on one surface of the resin substrate. Then similarly, the stress relaxation film/inorganic film/stress relaxation film used to produce the sample 7 of Example 2 was also formed on the other surface of the resin substrate, whereby the gas barrier resin substrate was manufactured. In this case, the stress relaxation film was 200 nm thick, and the inorganic film was 50 nm thick.

This gas barrier resin substrate was used as an OLED substrate and an OLED was produced in the procedure described in Example 6.

<<Evaluation of Characteristics of Each Sample>>

The sample 21 produced according to the aforementioned procedure was left to stand at 80° C. with a relative humidity of 90% RH for 300 hours according to the method described in Example 6. Then the sample was tested to evaluate the occurrence of a dark spot. It has been revealed that no dark spot was observed at all in this sample.

1. A gas barrier thin film laminate comprising an inorganic film and a stress relaxation film, wherein the stress relaxation film is formed by an atmospheric pressure plasma method, wherein two or more electric fields having different frequencies are applied to a discharge space in the atmospheric pressure plasma method.

2. The gas barrier thin film laminate of claim 1, wherein the stress relaxation film is produced by the atmospheric pressure plasma method by introducing a thin film forming gas into a plasma space, the thin film forming gas comprising an organic compound having an unsaturated bond or a ring structure.

3. The gas barrier thin film laminate of claim 1, wherein the stress relaxation film is produced by the atmospheric pressure plasma method by introducing a thin film forming gas into a plasma space, the thin film forming gas comprising:
an organic compound having an unsaturated bond or a ring structure; and
an organometallic compound.

4. The gas barrier thin film laminate of claim 2, wherein the organic compound having an unsaturated bond or a ring structure is at lest one selected from the group consisting of a (meth)acryl compound, an epoxy compound and an oxetane compound.

5. The gas barrier thin film laminate of claim 2, wherein the thin film forming gas comprises nitrogen gas as a main component.

6. The gas barrier thin film laminate of claim 2, wherein the thin film forming gas comprises, as an additive gas, at least one organic compound selected from the group consisting of a group of hydrocarbons, a group of alcohols and a group of organic acids.

7. The gas barrier thin film laminate of claim 1, wherein the inorganic film comprises at least one selected from the group consisting of a metal oxide, a metal nitride-oxide and a metal nitride, as a main component.

8. The gas barrier thin film laminate of claim 1, wherein the inorganic film is formed by an atmospheric pressure plasma method by applying two or more electric fields having different frequencies.

9. The gas barrier thin film laminate of claim 1, wherein an adhesive layer is provided between the stress relaxation film and the inorganic film.

10. The gas barrier thin film laminate of claim 9, wherein the adhesive layer is at least one selected from the group consisting of a metal oxide, a metal nitride-oxide and a metal nitride each containing 1 to 50% carbon.

11. A gas barrier resin substrate comprising a resin substrate having the gas barrier thin film laminate of claim 1 on one surface of the resin substrate.

12. The gas barrier resin substrate of claim 11, wherein the resin substrate has a glass transition temperature of 150° C. or more.

13. An organic EL device comprising:
a second substrate having thereon electrodes and an organic compound layer; and
a sealing film provided to cover the electrodes and the organic compound layer,
wherein the sealing film is the gas barrier thin film laminate of claim 1.

14. An organic EL device comprising:
a second substrate having thereon electrodes and an organic compound layer; and
a sealing film provided to cover the electrodes and the organic compound layer, the sealing film being adhered with the second substrate to seal the electrodes and the organic compound layer,
wherein the sealing film is the gas barrier resin substrate of claim 11.

15. An organic EL device comprising:
a second substrate having thereon electrodes and an organic compound layer; and
a sealing film provided to cover the electrodes and the organic compound layer,
wherein
the sealing film is the gas barrier thin film laminate of claim 1; and
the second substrate having thereon the electrodes and the organic compound layer is a gas barrier resin substrate comprising a resin substrate having the gas barrier thin film laminate of claim 1 on one surface of the resin substrate.

16. An organic EL device comprising:
a second substrate having thereon electrodes and an organic compound layer; and
a sealing film provided to cover the electrodes and the organic compound layer, the sealing film being adhered with the second substrate to seal the electrodes and the organic compound layer,
wherein
the sealing film is the gas barrier resin substrate of claim 11; and
the second substrate having thereon the electrodes and the organic compound layer is the gas barrier resin substrate of claim 11.
